(19) United States
(12) Patent Application Publication
(10) Pub. No.: US 2023/0250527 A1
(43) Pub. Date: Aug. 10, 2023

(54) METHOD FOR INSPECTING MASK, METHOD FOR MANUFACTURING MASK, APPARATUS FOR INSPECTING MASK, STORAGE MEDIUM, AND MASK

(71) Applicant: Dai Nippon Printing Co., Ltd., Tokyo (JP)

(72) Inventors: Yusuke SHIMIZU, Tokyo (JP); Hideyuki OKAMOTO, Tokyo (JP)

(73) Assignee: Dai Nippon Printing Co., Ltd., Tokyo (JP)

(21) Appl. No.: 18/159,310

(22) Filed: Jan. 25, 2023

(30) Foreign Application Priority Data
Jan. 31, 2022 (JP) 2022-013683

(51) Int. Cl. C23C 14/04; C23C 14/24

(52) U.S. Cl. CPC C23C 14/042; C23C 14/24

(57) ABSTRACT

A method for inspecting a mask may include a first calculation step of calculating the y components y₀ to yₙ of the coordinates of reference points in a y direction, an adjustment step of adjusting a tension so that a simple amplitude converted value ΔC calculated based on the y components y₀ to yₙ becomes less than or equal to a first threshold, the tension being applied to the mask, and a second evaluation step of evaluating linearity of the mask with reference to amplitude ΔS calculated based on the y components of the coordinates of the reference points of the mask under the tension adjusted in the adjustment step.

### CROSS REFERENCES TO RELATED APPLICATIONS

The present application contains subject matter related to Japanese Patent Application No. 2022-13683 filed in the Japan Patent Office on Jan. 31, 2022, the entire contents of which are incorporated herein by reference.

### BACKGROUND

### 1. Field

Embodiments of the present disclosure relates to a method for inspecting a mask, a method for manufacturing a mask, an apparatus for inspecting a mask, a storage medium, and a mask.

### 2. Description of the Related Art

Recently, in the field of electronic devices such as smartphones and tablet PCs, there has been market demand for high-definition display devices. A display device has a pixel density of, for example, 400 ppi or higher or 800 ppi or higher.

Organic EL display devices have attracted attention because of their high responsivity, low power consumption, and high contrast. As a method for forming pixels of an organic EL display device, there has been known a deposition method. The deposition method involves the use of a mask device to form pixels and electrodes in a desired pattern. The mask device includes a mask including through holes and a frame supporting the mask.

The frame has a side to which an end portion of the mask is fixed. The frame supports the mask with tension applied to the mask in an x direction. This restrains the mask from warping.

International Publication No. 2019/049600 is an example of related art.

### SUMMARY

The mask is constituted by a metal plate that may be distorted with respect to the x direction and/or a y direction. For example, the mask may have a side edge extending in a direction that is out of alignment with the x direction. For example, the mask may have a width extending in a direction that is out of alignment with the y direction. Such distortions are reduced to some degree by fixing the mask to the frame with tension applied to the mask. However, the degree of the reduction of the distortions depends on the individual masks.

In a method for inspecting a mask according to an embodiment of the present disclosure, the mask may include a first end portion and a second end portion that are opposite to each other in an x direction, a cell that is located between the first end portion and the second end portion and that includes a plurality of through holes, and n+1 (where n is a positive integer) reference points arranged in the x direction. The method may include a first calculation step of calculating y components y₀ to yₙ of coordinates of the reference points in a y direction orthogonal to the x direction, an adjustment step of adjusting a tension so that a simple amplitude converted value ΔC calculated based on the y components y₀ to yₙ becomes less than or equal to a first threshold, the tension being applied to the mask, and a second evaluation step of evaluating linearity of the mask with reference to amplitude ΔS calculated based on y components of coordinates of the reference points of the mask under the tension adjusted in the adjustment step.

The present disclosure makes it possible to efficiently inspect a mask.

### BRIEF DESCRIPTION OF THE DRAWINGS

FIG. 1 is a cross-sectional view showing an example of an organic device according to an embodiment of the present disclosure.

FIG. 2 is a diagram showing an example of a deposition apparatus including a mask device.

FIG. 3 is a plan view showing an example of the mask device.

FIG. 4 is a plan view showing an example of a mask.

FIG. 5 is a plan view showing examples of through holes of a mask.

FIG. 6 is a cross-sectional view showing examples of through holes of a mask.

FIG. 7 is a diagram showing an example of a rolling step of rolling a parent material.

FIG. 8 is a diagram showing an example of a distorted metal plate.

FIG. 9 is a diagram showing a processing step of forming a plurality of through holes in a metal plate.

FIG. 10A is a plan view showing an example of a distorted mask.

FIG. 10B is a plan view showing an example of a distorted mask.

FIG. 11A is a diagram for explaining a configuration of a mask with higher-order component distortion.

FIG. 11B is a diagram for explaining a first cross point of the mask.

FIG. 12A is a plan view showing an example of a mask including a third end including one concave portion and one convex portion.

FIG. 12B is a plan view showing an example of a mask including a third end including two concave portions and one convex portion.

FIG. 13A is a plan view showing an example of a mask with higher-order component distortion.

FIG. 13B is a diagram for explaining a third cross point of the mask.

FIG. 14 is a plan view showing an example of a cell including a third side including one concave portion and one convex portion.

FIG. 15 is a plan view showing a step of fixing a mask to a frame.

FIG. 16 is a plan view showing a step of fixing a mask to a frame.

FIG. 17A is a plan view showing an example of a mask under tension.

FIG. 17B is a plan view showing an example of a mask under tension.

FIG. 18 is a flow chart showing an example of a method for inspecting a mask.

FIG. 19 is a plan view showing an example of a mask with set reference points.

FIG. 20 is a plan view showing an example of a mask with set reference points.

FIG. 21 is a flow chart showing an example of a first calculation step.

FIG. 22 is a plan view showing an example of a step of correcting a mask.

FIG. 23 is a plan view showing an example of a step of correcting a mask.

FIG. 24 is a diagram showing an example of an inspection apparatus.

FIG. 25 is a graph showing examples of yᵢ, yᵢ′, and Yᵢ.

FIG. 26 is a graph showing examples of yᵢ, yᵢ′, and Yᵢ.

FIG. 27 is a flow chart showing an example of a method for inspecting a mask.

FIG. 28 is a plan view showing an example of a mask under parallelizing tension.

FIG. 29 is a plan view showing an example of a mask under parallelizing tension.

FIG. 30 is a graph showing examples of yᵢ, yᵢ′, Yᵢ, and yᵢ″.

FIG. 31 is a graph showing examples of yᵢ, yᵢ′, and Yᵢ.

FIG. 32 is a graph showing a relationship between ΔC and ΔS.

FIG. 33 is a graph showing yᵢ and yᵢ″ in a mask of Example 1.

FIG. 34 is a graph showing yᵢ and yᵢ″ in a mask of Example 2.

FIG. 35 is a graph showing yᵢ and yᵢ″ in a mask of Example 3.

### DESCRIPTION OF THE EMBODIMENTS

In the present specification and the present drawings, unless otherwise specifically described, terms, such as “substrate” “base material”, “plate”, “sheet”, and “film”, that mean a matter forming the basis of a certain component are not distinguished from one another solely on the basis of the difference in designation.

In the present specification and the present drawings, unless otherwise specifically described, shapes and geometric conditions, terms, such as “parallel” and “orthogonal”, that specify the extents of the shapes and the geometric conditions, and values, such as lengths and angles, that specify the extents of the shapes and the geometric conditions are not bound by the strict sense but are construed with the inclusion of a range of extents to which similar functions may be expected.

In the present specification and the present drawings, unless otherwise specifically described, cases where a certain component such as a certain member or a certain region is “on top of” or “under”, “on the upper side” or “on the lower side”, or “above” or “below” another component such as another member or another region encompass cases where a certain component is in direct contact with another component. Furthermore, the cases also encompass cases where a different component is included between a certain component and another component, i.e. cases where a certain component is in indirect contact with another component. Unless otherwise specifically described, the words and phrases such as “on top of”, “on the upper side”, “above”, “under”, “on the lower side”, and “below” may be turned upside down in meaning.

In the present specification and the present drawings, unless otherwise specifically described, identical components or components having similar functions may be assigned identical or similar signs, and a repeated description of such components may be omitted. For convenience of explanation, dimensional ratios in the drawings may be different from actual ratios, or some components may be omitted from the drawings.

In the present specification and the present drawings, unless otherwise specifically described, an embodiment of the present specification may be combined with another embodiment unless a contradiction arises. Other embodiments may be combined with each other unless a contradiction arises.

In the present specification and the present drawings, unless otherwise specifically described, in a case where multiple steps are disclosed regarding a method such as a manufacturing method, another step that is not disclosed may be executed between steps that are disclosed. The steps that are disclosed may be executed in any order unless a contradiction arises.

In the present specification and the present drawings, unless otherwise specifically described, a range expressed by the preposition “to” includes a numerical value placed before “to” and a numerical value placed after “to”. For example, a range defined by the expression “y₀ to y₆” is identical to a range defined by the expression “y₀, y₁, y₂, y₃, y₄, y₅, and y₆”.

An embodiment of the present disclosure is described in detail below with reference to the drawings. It should be noted that the embodiment to be described below Is one example among embodiments of the present disclosure, and the present disclosure should not be construed only within the limits of these embodiments.

A first aspect of the present disclosure is directed to a method for inspecting a mask,

the mask including a first end portion and a second end portion that are opposite to each other in an x direction, a cell that is located between the first end portion and the second end portion and that includes a plurality of through holes, and n+1 (where n is a positive integer) reference points arranged in the x direction,

the method including:

a first calculation step of calculating y components y₀ to yₙ of coordinates of the reference points in a y direction orthogonal to the x direction;

an adjustment step of adjusting a tension so that a simple amplitude converted value ΔC calculated based on the y components y₀ to yₙ becomes less than or equal to a first threshold, the tension being applied to the mask; and

a second evaluation step of evaluating linearity of the mask with reference to amplitude ΔS calculated based on y components of coordinates of the reference points of the mask under the tension adjusted in the adjustment step.

A second aspect of the present disclosure may be directed to the method according to the first aspect, wherein the first calculation step may include a correction step of correcting the mask so that the first end portion and the second end portion become parallel to each other and a measuring step of measuring coordinates of the reference points of the mask thus corrected.

A third aspect of the present disclosure may be directed to the method according to the first or second aspect, wherein the adjustment step may include calculating amplitude magnifications Y₀ to Yₙ by multiplying the y components y₀ to yₙ by y components y′₀ to y′ₙ of a cosine function y′ that simulates a cosine wave, calculating an average amplitude magnification Mag.Y that is an average of the amplitude magnifications Y₀ to Yₙ, calculating simple amplitude converted components y″₀ to y″ₙ by multiplying the average amplitude magnification Mag.Y by the y components y₀ to y′ₙ, and calculating the simple amplitude converted value ΔC as a difference between maximum and minimum values of the simple amplitude converted components y″₀ to y″ₙ.

A fourth aspect of the present disclosure may be directed to the method according to each of the first to third aspects, wherein the second evaluation step may include judging the mask as an acceptable product in a case where a difference ΔS between maximum and minimum values of the y components y₀ to yₙ is greater than or equal to a third threshold and less than or equal to a fourth threshold.

A fifth aspect of the present disclosure may be directed to the method according to the fourth aspect, wherein the third threshold may be 1.8×ΔC+0.40 μm, and the fourth threshold may be 1.8×ΔC+2.00 μm.

A sixth aspect of the present disclosure may be directed to the method according to each of the first to fifth aspects, wherein the first threshold may be 1.11 μm.

A seventh aspect of the present disclosure may be directed to the method according to each of the first to sixth aspects, further including a first evaluation step of exempting the mask from evaluation in a case where the simple amplitude converted value ΔC is less than a second threshold.

An eighth aspect of the present disclosure may be directed to the method according to the seventh aspect, wherein the second threshold may be 0.20 μm.

A ninth aspect of the present disclosure may be directed to the method according to the seventh or eighth aspect, herein the second evaluation step may be executed in a case where the simple amplitude converted value ΔC is greater than or equal to the second threshold and less than or equal to the first threshold.

A tenth aspect of the present disclosure is directed to a method for manufacturing a mask, including the steps of:

preparing a metal plate;

forming a plurality of through holes in the metal plate;

obtaining the mask by partially cutting out the metal plate with the through holes formed in the metal plate; and

inspecting the mask using the method according to each of the first to ninth aspects.

An eleventh aspect of the present disclosure is directed to an apparatus for inspecting a mask,

the mask including a first end portion and a second end portion that are opposite to each other in an x direction, a cell that is located between the first end portion and the second end portion and that includes a plurality of through holes, and n+1 (where n is a positive integer) reference points arranged in the x direction,

the apparatus including:

a first calculation device that calculates y components y₀ to yₙ of coordinates of the reference points in a y direction orthogonal to the x direction;

an adjustment device that adjusts a tension so that a simple amplitude converted value ΔC calculated based on the y components y₀ to yₙ becomes less than or equal to a first threshold, the tension being applied to the mask; and

a second evaluation device that evaluates linearity of the mask with reference to amplitude ΔS calculated based on y components of coordinates of the reference points of the mask under the tension adjusted by the adjustment device.

A twelfth aspect of the present disclosure may be directed to the apparatus according to the eleventh aspect, wherein

the first calculation device may include a correction device that corrects the mask so that the first end portion and the second end portion become parallel to each other and a measuring device that measures coordinates of the reference points of the mask thus corrected.

A thirteenth aspect of the present disclosure may be directed to the apparatus according to the eleventh or twelfth aspect, wherein the adjustment device may calculate amplitude magnifications Y₀ to Yₙ by multiplying the y components y₀ to yₙ by y components y′₀ to y′ₙ of a cosine function y′ that simulates a cosine wave, calculate an average amplitude magnification Mag.Y that is an average of the amplitude magnifications Y₀ to Yₙ, calculate simple amplitude converted components y″₀ to y″ₙ by multiplying the average amplitude magnification Mag.Y by the y components y′₀ to y′ₙ, and calculate the simple amplitude converted value ΔC as a difference between maximum and minimum values of the simple amplitude converted components y″₀ to y″ₙ.

A fourteenth aspect of the present disclosure is directed to a program for causing a computer to function as the adjustment device and the second evaluation device of the apparatus according to each of the eleventh to thirteenth aspects.

A fifteenth aspect of the present disclosure is directed to a computer-readable non-transient storage medium including the program according to the fourteenth aspect.

A sixteenth aspect of the present disclosure is directed to a mask including:

a first end portion and a second end portion that are opposite to each other in an x direction;

an intermediate portion including one or more cells that are located between the first end portion and the second end portion and each of which includes a plurality of through holes; and

n+1 (where n is a positive integer) arranged in the x direction,

wherein

the mask has an adjusted tension,

the adjusted tension is a tension at which a simple amplitude converted value ΔC calculated based on y components y₀ to yₙ of coordinates of the reference points In a y direction orthogonal to the x direction can be made less than or equal to a first threshold value,

the first threshold is 1.11 μm,

the simple amplitude converted value ΔC is a difference between maximum and minimum values of simple amplitude converted components y″₀ to y″ₙ,

the simple amplitude converted components y″₀ to y″ₙ are calculated by multiplying an average amplitude magnification Mag.Y by y components y′₀ to y′ₙ of a cosine function that simulates a cosine wave,

the average amplitude magnification Mag.Y is an average of amplitude magnifications Y₀ to Yₙ calculated by multiplying the y components y₀ to yₙ by the y components y′₀ to y′ₙ,

when under the adjusted tension, the mask has amplitude ΔS that is greater than or equal to a third threshold and less than or equal to a fourth threshold,

the amplitude ΔS is a difference between maximum and minimum values of y components y₀ to yₙ of coordinates of the reference points of the mask under the adjusted tension,

the third threshold is 1.8×ΔC+0.40 μm, and

the fourth threshold is 1.8×ΔC+2.00 μm.

A seventeenth aspect of the present disclosure may be directed to the mask according to the sixteenth aspect, wherein the y components y₀ to yₙ may be calculated by measuring coordinates of the reference points with the mask corrected so that the first end portion and the second end portion become parallel to each other.

An eighteenth aspect of the present disclosure may be directed to the mask according to the sixteenth or seventeenth aspect, wherein the simple amplitude converted value ΔC may be greater than or equal to 0.20 μm.

A nineteenth aspect of the present disclosure may be directed to the mask according to the sixteenth or seventeenth aspect, further including: a first end and a second end that are ends of the mask in the x direction; and a third end and a fourth end that are ends of the mask in the y direction. Each of the one or more cells may include a cell third contour extending along the third end, a cell fourth end extending along the fourth end, a cell first contour extending from a cell first end of the cell third contour to a cell first end of the cell fourth contour, and a cell second contour extending from a cell second end of the cell third contour to a cell second end of the cell fourth end. The cell third contours of the one or more cells may include at least one inner portion and at least one outer portion with the mask corrected so that the first end portion and the second end portion become parallel to each other. The inner portion is located further inward than a third straight line. The outer portion is located further outward than the third straight line. The third straight line is an imaginary line connecting a thirty-first cross point with a forty-first cross point. The thirty-first cross point is a point of intersection of the cell first contour and the cell third contour of one of the cells that is closest to the first end portion. The forty-first cross point is a point of intersection of the cell second contour and the cell third contour of one of the cells that is closest to the second end portion.

A twentieth aspect of the present disclosure may be directed to the mask according to the sixteenth or seventeenth aspect, further including: a first end and a second end that are ends of the mask in the x direction; and a third end and a fourth end that are ends of the mask in the y direction. Each of the one or more cells may include a cell third contour extending along the third end, a cell fourth end extending along the fourth end, a cell first contour extending from a cell first end of the cell third contour to a cell first end of the cell fourth contour, and a cell second contour extending from a cell second end of the cell third contour to a cell second end of the cell fourth end. The cell third contours of the one or more cells may include at least one inner portion and at least one outer portion with no tension being applied to the mask. The inner portion is located further inward than a third straight line. The outer portion is located further outward than the third straight line. The third straight line is an imaginary line connecting a thirty-first cross point with a forty-first cross point. The thirty-first cross point is a point of intersection of the cell first contour and the cell third contour of one of the cells that is closest to the first end portion. The forty-first cross point is a point of intersection of the cell second contour and the cell third contour of one of the cells that is closest to the second end portion.

An embodiment of the present disclosure is described in detail below with reference to the drawings. It should be noted that the embodiment to be described below is one example among embodiments of the present disclosure, and the present disclosure should not be construed only within the limits of these embodiments.

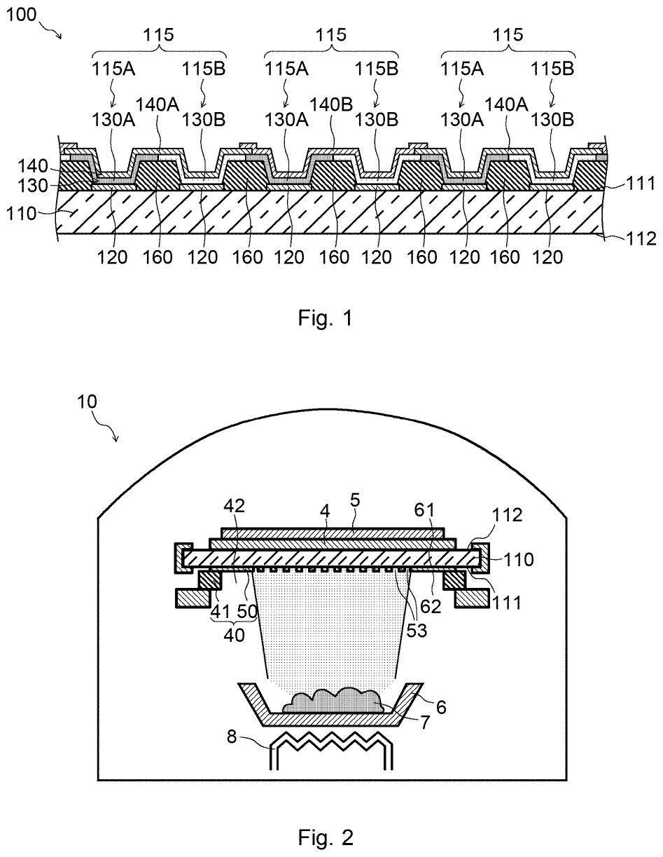

An organic device 100 including elements that are formed by using masks is described. FIG. 1 is a cross-sectional view showing an example of the organic device 100.

The organic device 100 includes a substrate 110 including a first surface 111 and a second surface 112 and a plurality of elements 115 located on the first surface 111 of the substrate 110. The elements 115 are for example pixels. The elements 115 may be arranged along an in-plane direction of the first surface 111. The substrate 110 may include two or more types of elements 115. For example, the substrate 110 may include first elements 115A and second elements 115B. Although not illustrated, the substrate 110 may include third elements. The first elements 115A, the second elements 115B, and the third elements are for example red pixels, blue pixels, and green pixels.

Each of the elements 115 may include a first electrode 120, an organic layer 130 located on top of the first electrode 120, and a second electrode 140 located on top of the organic layer 130. An element that is formed by using a mask may be an organic layer 130, or may be a second electrode 140. An element that is formed by using a mask is also referred to as “deposited layer”.

The organic device 100 may include an insulating layer 160 located between two first electrodes 120 adjacent to each other in planar view. The insulating layer 160 contains, for example, polyimide. The insulating layer 160 may overlap an end of a first electrode 120 in planar view.

The organic device 100 may be of an active matrix type. For example, although not Illustrated, the organic device 100 may include switches that are electrically connected separately to each of the elements 115. The switches are for example transistors. Each of the switches can control the tuning on and turning off of a voltage or an electric current to the corresponding one of the elements 115.

The substrate 110 may be a plate member having insulation properties. The substrate 110 preferably has transparency that allows passage of light. The substrate 110 can be made of a material such as either a rigid material such as quartz glass, Pyrex (registered trademark) glass, a synthetic quartz plate, or alkali-free glass or a flexible material such as a resin film, an optical resin plate, or thin glass. Further, the base material may be a layered product including a resin film and a barrier layer(s) on one or both surfaces of the resin film.

Each of the elements 115 is configured to achieve some sort of function through either the application of a voltage between the first electrode 120 and the second electrode 140 or the flow of an electric current between the first electrode 120 and the second electrode 140. For example, in a case where the element 115 is a pixel of an organic EL display device, the element 115 can emit light that constitutes a picture.

The first electrode 120 contains a material having electric conductivity. For example, the first electrode 120 contains a metal, a metal oxide having electric conductivity, an inorganic material having electric conductivity, or other materials. The first electrode 120 may contain a metal oxide having transparency and electric conductivity, such as indium tin oxide (ITO) or indium zinc oxide (IZO).

The organic layer 130 contains an organic material. The passage of an electric current through the organic layer 130 allows the organic layer 130 to fulfill some sort of function. Usable examples of the organic layer 130 include a luminescent layer that emits light with the passage of an electric current. The organic layer 130 may contain an organic semiconductor material. Properties such as transmittance and refractive index of the organic layer 130 may be adjusted as appropriate.

As shown in FIG. 1, the organic layer 130 may include a first organic layer 130A and a second organic layer 130B. The first organic layer 130A is included in a first element 115A. The second organic layer 130B is included in a second element 115B. Although not illustrated, the organic layer 130 may include a third organic layer included in a third element. The first organic layer 130A, the second organic layer 130B, and the third organic layer are for example a red luminescent layer, a blue luminescent layer, and a green luminescent layer.

The application of a voltage between the first electrode 120 and the second electrode 140 causes an electric current to flow through the organic layer 130. In a case where the organic layer 130 is a luminescent layer, light is emitted from the organic layer 130, and the light is extracted outward from the second electrode 140 or the first electrode 120.

The organic layer 130 may further include a hole injection layer, a hole transport layer, an electron transport layer, an electron injection layer, a charge generating layer, or other layers.

The second electrode 140 contains a material having electric conductivity, such as a metal. The second electrode 140 is formed on top of the organic layer 130 by a deposition method that involves the use of a mask. The second electrode 140 can be made of a material such as platinum, gold, silver, copper, iron, tin, chromium, aluminum, indium, lithium, sodium, potassium, calcium, magnesium, indium tin oxide (ITO), indium zinc oxide (IZO), or carbon. These materials may each be used alone, or two or more of them may be used in combination. When two or more of these materials are used, layers made separately of each of the materials may be stacked. Further, an alloy containing two or more of these materials may be used. For example, a magnesium alloy such as MgAg, an aluminum alloy such as AlLi, AlCa, or AlMg can be used. MgAg is also referred to as magnesium silver. Magnesium silver is favorably used as a material of the second electrode 140. An alkali metal or alkali earth metal alloy or other materials may be used. For example, lithium fluoride, sodium fluoride, potassium fluoride, or other materials may be used.

The second electrode 140 may be a common electrode. For example, the second electrode 140 of one element 115 may be electrically connected to the second electrode 140 of another element 115.

The second electrode 140 may be composed of one layer. For example, the second electrode 140 may be a layer that is formed by a deposition step that involves the use of one mask.

Alternatively, as shown in FIG. 1, the second electrode 140 may Include a first layer 140A and a second layer 140B. The first layer 140A may be a layer that is formed by a deposition method that involves the use of a first mask. The second layer 140B may be a layer that is formed by a deposition method that involves the use of a second mask. In this way, the second electrode 140 may be formed using two or more masks. This increases the degree of freedom of a pattern of second electrodes 140 in planar view. For example, the organic device 100 can include a region where no second electrode 140 is present in planar view. The region where no second electrode 140 is present can have a higher transmittance than a region where a second electrode 140 is present.

As shown in FIG. 1, an end portion of the first layer 140A and an end portion of the second layer 140B may partially overlap each other. This allows the first layer 140A and the second layer 140B to be electrically connected to each other.

Although not illustrated, the second electrode 140 may include another layer such as a third layer. Another layer such as the third layer may be electrically connected to the first layer 140A and the second layer 140B.

The following description uses the term and sign “second electrode 140” to describe a configuration common to the first layer 140A, the second layer 140B, the third layer, or other layers.

Next, a method for forming elements such as the organic layer 130 and the second electrode 140 by a deposition method. FIG. 2 is a diagram showing a deposition apparatus 10. The deposition apparatus 10 executes a deposition process of depositing a deposited material on the substrate 110.

As shown in FIG. 2, the deposition apparatus 10 may include a deposition source 6, a heater 8, and a mask device 40 inside thereof. The deposition apparatus 10 may include exhaust means for bringing the interior of the deposition apparatus 10 into a vacuum atmosphere. The deposition source 6 is for example a crucible. The deposition source 6 accommodates a deposited material 7 such as an organic material or a metallic material. The heater 8 heats the deposition source 6 to evaporate the deposited material 7 in a vacuum atmosphere.

As shown in FIG. 2, the mask device 40 may Include at least one mask 50 and a frame 41 supporting the mask 50. The frame 41 may include an opening 42. The mask 50 may be fixed to the frame 41 so as to pass transversely across the opening 42 in planar view. The frame 41 may support the mask 50 while stretching the mask 50 in a direction parallel with the length of the mask 50.

As shown in FIG. 2, the mask device 40 is placed in the deposition apparatus 10 so that the mask 50 faces the substrate 110. The mask 50 includes a plurality of through holes 53 that through which a portion of the deposited material 7 having flown from the deposition source 6 passes. In the following description, a surface of the mask 50 located toward the substrate 110 is also referred to as “front surface 61”. A surface of the mask 50 located opposite the front surface 61 is also referred to as “back surface 62”.

As shown in FIG. 2, the deposition apparatus 10 may include a cooling plate 4 disposed toward the second surface 112 of the substrate 110. The cooling plate 4 may have inside thereof a flow passage through which to circulate refrigerant. The cooling plate 4 can suppress a rise in temperature of the substrate 110 during a deposition step.

As shown in FIG. 2, the deposition apparatus 10 may include a magnet 5 disposed toward the second surface 112 of the substrate 110. The magnet 5 may be disposed on a surface of the cooling plate 4 that faces away from the mask device 40. The magnet 5 magnetically attracts the mask 50 toward the substrate 110. This makes it possible to reduce or eliminate a gap between the mask 50 and the substrate 110. This makes it possible to reduce the occurrence of a shadow in the deposition step. The term “shadow” as used herein means a phenomenon in which the deposited material 7 enters the gap between the mask 50 and the substrate 110 and thereby makes the thickness of the second electrode 140 uneven. An electrostatic chuck may be used to electrostatically attract the mask 50 toward the substrate 110.

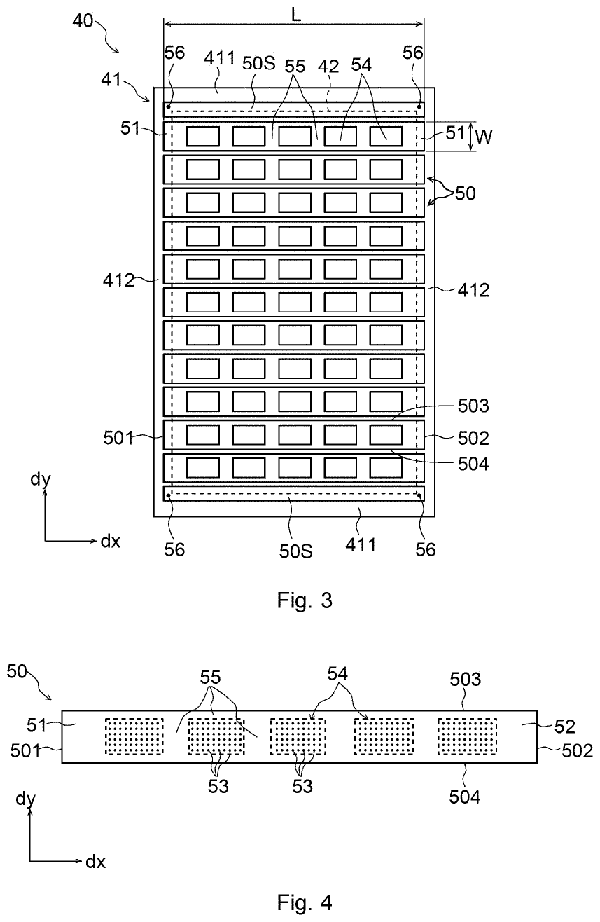

FIG. 3 is a plan view showing an example of the mask device 40. The shape of the mask 50 may be a rectangle having a length direction and a width direction orthogonal to the length direction. A dimension of the mask 50 in the length direction is smaller than a dimension of the mask 50 in the width direction. In the following description, the length direction is also referred to as “x direction”, and the width direction is also referred to as “y direction”. The mask 50 may include a first end 501, a second end 502, a third end 503, and a fourth end 504. The first end 501 and the second end 502 are ends of the mask 50 in the x direction dx. The third end 503 and the fourth end 504 are ends of the mask 50 in the y direction dy.

The mask device 40 may include a plurality of masks 50 arranged in the y direction dy. Each of the masks 50 may be fixed to the frame 41, for example, by welding at both end portions in the x direction dx.

In FIG. 3, reference sign L denotes a dimension of the mask 50 in the x direction dx, i.e. the length of the mask 50. The dimension L may for example be greater than or equal to 150 mm, greater than or equal to 300 mm, greater than or equal to 450 mm, or greater than or equal to 600 mm. The dimension L may for example be less than or equal to 750 mm, less than or equal to 1000 mm, less than or equal to 1500 mm, or less than or equal to 2000 mm. The dimension L may fall within a range defined by a first group consisting of 150 mm, 300 mm, 450 mm, and 600 mm and/or a second group consisting of 750 mm, 1000 mm, 1500 mm, and 2000 mm. [symbol] The dimension L may fall within a range defined by a combination of any one of the values included in the aforementioned first group and any one of the values included in the aforementioned second group. The dimension L may fall within a range defined by a combination of any two of the values included in the aforementioned first group. The dimension L may fall within a range defined by a combination of any two of the values included in the aforementioned second group. The dimension L may for example be greater than or equal to 150 mm and less than or equal to 2000 mm, greater than or equal to 150 mm and less than or equal to 1500 mm, greater than or equal to 150 mm and less than or equal to 1000 mm, greater than or equal to 150 mm and less than or equal to 750 mm, greater than or equal to 150 mm and less than or equal to 600 mm, greater than or equal to 150 mm and less than or equal to 450 mm, greater than or equal to 150 mm and less than or equal to 300 mm, greater than or equal to 300 mm and less than or equal to 2000 mm, greater than or equal to 300 mm and less than or equal to 1500 mm, greater than or equal to 300 mm and less than or equal to 1000 mm, greater than or equal to 300 mm and less than or equal to 750 mm, greater than or equal to 300 mm and less than or equal to 600 mm, greater than or equal to 300 mm and less than or equal to 450 mm, greater than or equal to 450 mm and less than or equal to 2000 mm, greater than or equal to 450 mm and less than or equal to 1500 mm, greater than or equal to 450 mm and less than or equal to 1000 mm, greater than or equal to 450 mm and less than or equal to 750 mm, greater than or equal to 450 mm and less than or equal to 600 mm, greater than or equal to 600 mm and less than or equal to 2000 mm, greater than or equal to 600 mm and less than or equal to 1500 mm, greater than or equal to 600 mm and less than or equal to 1000 mm, greater than or equal to 600 mm and less than or equal to 750 mm, greater than or equal to 750 mm and less than or equal to 2000 mm, greater than or equal to 750 mm and less than or equal to 1500 mm, greater than or equal to 750 mm and less than or equal to 1000 mm, greater than or equal to 1000 mm and less than or equal to 2000 mm, greater than or equal to 1000 mm and less than or equal to 1500 mm, or greater than or equal to 1500 mm and less than or equal to 2000 mm.

In FIG. 3, reference sign W denotes a dimension of the mask 50 in the y direction dy, i.e. the width of the mask 50. The dimension W may for example be greater than or equal to 50 mm, greater than or equal to 100 mm, greater than or equal to 150 mm, or greater than or equal to 200 mm. The dimension W may for example be less than or equal to 250 mm, less than or equal to 300 mm, less than or equal to 350 mm, or less than or equal to 400 mm. The dimension W may fall within a range defined by a first group consisting of 50 mm, 100 mm, 150 mm, and 200 mm and/or a second group consisting of 250 mm, 300 mm, 350 mm, and 400 mm. The dimension W may fall within a range defined by a combination of any one of the values included in the aforementioned first group and any one of the values included in the aforementioned second group. The dimension W may fall within a range defined by a combination of any two of the values included in the aforementioned first group. The dimension W may fall within a range defined by a combination of any two of the values included in the aforementioned second group. The dimension W may for example be greater than or equal to 50 mm and less than or equal to 400 mm, greater than or equal to 50 mm and less than or equal to 350 mm, greater than or equal to 50 mm and less than or equal to 300 mm, greater than or equal to 50 mm and less than or equal to 250 mm, greater than or equal to 50 mm and less than or equal to 200 mm, greater than or equal to 50 mm and less than or equal to 150 mm, greater than or equal to 50 mm and less than or equal to 100 mm, greater than or equal to 100 mm and less than or equal to 400 mm, greater than or equal to 100 mm and less than or equal to 350 mm, greater than or equal to 100 mm and less than or equal to 300 mm, greater than or equal to 100 mm and less than or equal to 250 mm, greater than or equal to 100 mm and less than or equal to 200 mm, greater than or equal to 100 mm and less than or equal to 150 mm, greater than or equal to 150 mm and less than or equal to 400 mm, greater than or equal to 150 mm and less than or equal to 350 mm, greater than or equal to 150 mm and less than or equal to 300 mm, greater than or equal to 150 mm and less than or equal to 250 mm, greater than or equal to 150 mm and less than or equal to 200 mm, greater than or equal to 200 mm and less than or equal to 400 mm, greater than or equal to 200 mm and less than or equal to 350 mm, greater than or equal to 200 mm and less than or equal to 300 mm, greater than or equal to 200 mm and less than or equal to 250 mm, greater than or equal to 250 mm and less than or equal to 400 mm, greater than or equal to 250 mm and less than or equal to 350 mm, greater than or equal to 250 mm and less than or equal to 300 mm, greater than or equal to 300 mm and less than or equal to 400 mm, greater than or equal to 300 mm and less than or equal to 350 mm, or greater than or equal to 350 mm and less than or equal to 400 mm.

The frame 41 may have rectangular contours. For example, the frame 41 may include a pair of first side regions 411 extending in the x direction dx and a pair of second side regions 412 extending in the y direction dy. The end portions of the mask 50 in the x direction dx may be fixed to the second side regions 412. The mask 50 may be fixed to the second side regions 412 so that tension is applied to the mask 50 in the x direction dx. The second side regions 412 may be longer than the first side regions 411. The opening 42 of the frame 41 may be surrounded by the pair of first side regions 411 and the pair of second side regions 412.

FIG. 4 is a plan view showing an example of a mask 50. As shown in FIGS. 3 and 4, the mask 50 may include a first end portion 51, a second end portion 52, cells 54, and a surrounding region 55. The first end portion 51 and the second end portion 52 are opposite to each other in the x direction. The cells 54 are located between the first end portion 51 and the second end portion 52. Each of the cells 54 includes a plurality of through holes 53 regularly arranged. In a case where the mask 50 is used to fabricate a display device such as an organic EL display device, one cell 54 corresponds to a display area of one organic EL display device. The surrounding region 55 is a region surrounding the cells 54. The first end portion 51 is a region spreading from the first end 501 to a cell 54. The second end portion 52 is a region spreading from the second end 502 to a cell 54. The first end portion 51 and the second end portion 52 are fixed to the second side regions 412.

As shown in FIGS. 3 and 4, the mask 50 may include two or more cells 54 arranged in the x direction dx. In this case, the first end portion 51 is a region between a cell 54 that is closest to the first end 501 and the first end 501, and the second end portion 52 is a region between a cell 54 that is closest to the second end 502 and the second end 502.

As shown in FIG. 3, the mask device 40 may include an alignment mask 50S located between a first side region 411 and a mask 50. For example, the mask device 40 may include a first alignment mask 50S partially overlapping a first first side region 411 and a second alignment mask 50S partially overlapping a second first side region 411.

The alignment mask 50S may include a mark 56. The alignment mask 50S may be located in a region of the alignment mask 50S overlapping the frame 41. The first alignment mask 50S may include a first mark 56 overlapping a first second side region 412 and a second mark 56 overlapping a second second side region 412. The second alignment mask 50S may include a third mark 56 overlapping the first second side region 412 and a fourth mark 56 overlapping the second second side region 412. Although not illustrated, the first to fourth marks 56 may not overlap the frame 41. The x direction dx, the y direction dy, and an x-y coordinate system may be set based on the first to fourth marks 56. The coordinates of the after-mentioned reference points may be measured in an x-y coordinate system set based on the first to fourth marks 56.

The mark 56 is configured in any way as long as the mark 56 can be recognized. The mark 56 may be a through hole bored through the alignment mask 50S. The mark 56 may for example be a convex portion or a concave portion located on or in the front or back surface of the alignment mask 50S.

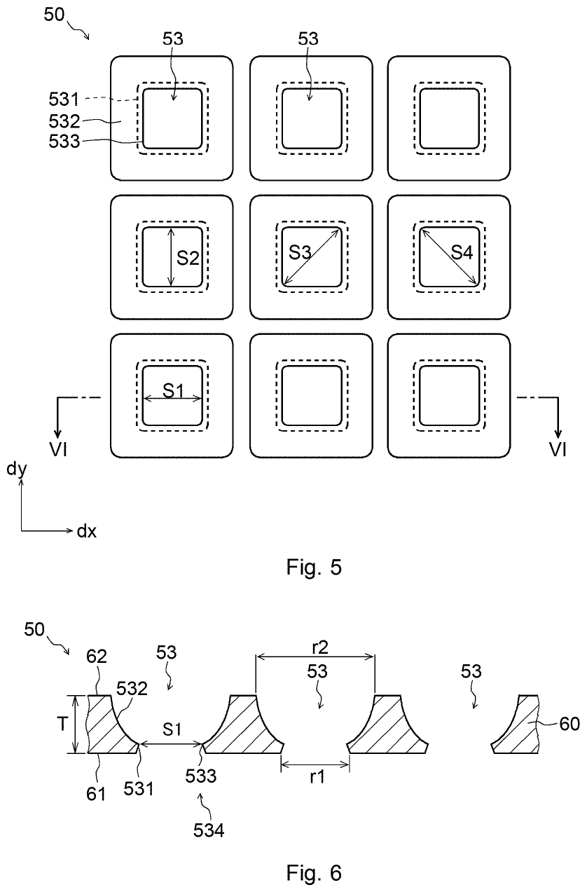

FIG. 5 is a plan view showing examples of through holes 53 of a mask 50. As shown in FIG. 5, the through holes 53 may be regularly arranged in the x direction dx and the y direction dy.

FIG. 6 is a cross-sectional view of the mask 50 as taken along line VI-VI in FIG. 5. As shown in FIG. 6, the mask 50 includes a metal plate 60 including the front surface 61 and the back surface 62. The through holes 53 are bored from the front surface 61 to the back surface 62.

Each of the through holes 53 may include a first concave portion 531 located in the front surface 61 and a second concave portion 532 located in the back surface 62. The first concave portion 531 and the second concave portion 532 are connected to each other at a connecting portion 533. The first concave portion 531 and the second concave portion 532 are formed by processing the metal plate 60, for example, by etching or lasering from the front surface 61 and the back surface 62.

In a planar view, a dimension r2 of the second concave portion 532 may be larger than a dimension r1 of the first concave portion 531. In a planar view, the contours of the connecting portion 533 may be surrounded by the contours of the first concave portion 531 and the contours of the second concave portion 532. The contours of the through hole 53 in planar view may reach its minimum at the connecting portion 533.

In FIG. 5, reference signs S1 to S4 each denote a dimension of a through hole 53 in one in-plane direction of the mask 50. In the after-mentioned inspection method, the dimensions S1 to S4 or other dimensions may be measured. The dimensions S1 to S4 may be measured based on light passing through the through holes 53. For example, parallel light falls on the front surface 61 along a direction normal to the mask 50. Based on the dimensions of a region occupied in an in-plane direction of the mask 50 by light emitted through the back surface 62, the dimensions S1 to S4 or other dimensions are calculated. The parallel light may fall on the back surface 62.

As an example of a dimension of a through hole 53, the range of numerical values of the dimension S1 is described. The dimension S1 may for example be greater than or equal to 10 μm, greater than or equal to 15 μm, greater than or equal to 20 μm, or greater than or equal to 25 μm. The dimension S1 may for example be less than or equal to 40 μm, less than or equal to 45 μm, less than or equal to 50 μm, or less than or equal to 55 μm. The dimension S1 may fall within a range defined by a first group consisting of 10 μm, 15 μm, 20 μm, and 25 μm and/or a second group consisting of 40 μm, 45 μm, 50 μm, and 55 μm. The dimension S1 may fall within a range defined by a combination of any one of the values included in the aforementioned first group and any one of the values included in the aforementioned second group. The dimension S1 may fall within a range defined by a combination of any two of the values included in the aforementioned first group. The dimension S1 may fall within a range defined by a combination of any two of the values included in the aforementioned second group. The dimension S1 may for example be greater than or equal to 10 μm and less than or equal to 55 μm, greater than or equal to 10 μm and less than or equal to 50 μm, greater than or equal to 10 μm and less than or equal to 45 μm, greater than or equal to 10 μm and less than or equal to 40 μm, greater than or equal to 10 μm and less than or equal to 25 μm, greater than or equal to 10 μm and less than or equal to 20 μm, greater than or equal to 10 μm and less than or equal to 15 μm, greater than or equal to 15 μm and less than or equal to 55 μm, greater than or equal to 15 μm and less than or equal to 50 μm, greater than or equal to 15 μm and less than or equal to 45 μm, greater than or equal to 15 μm and less than or equal to 40 μm, greater than or equal to 15 μm and less than or equal to 25 μm, greater than or equal to 15 μm and less than or equal to 20 μm, greater than or equal to 20 μm and less than or equal to 55 μm, greater than or equal to 20 μm and less than or equal to 50 μm, greater than or equal to 20 μm and less than or equal to 45 μm, greater than or equal to 20 μm and less than or equal to 40 μm, greater than or equal to 20 μm and less than or equal to 25 μm, greater than or equal to 25 μm and less than or equal to 55 μm, greater than or equal to 25 μm and less than or equal to 50 μm, greater than or equal to 25 μm and less than or equal to 45 μm, greater than or equal to 25 μm and less than or equal to 40 μm, greater than or equal to 40 μm and less than or equal to 55 μm, greater than or equal to 40 μm and less than or equal to 50 μm, greater than or equal to 40 μm and less than or equal to 45 μm, greater than or equal to 45 μm and less than or equal to 55 μm, greater than or equal to 45 μm and less than or equal to 50 μm, or greater than or equal to 50 μm and less than or equal to 55 μm.

The thickness T of the metal plate 60 may for example be greater than or equal to 8 μm, greater than or equal to 10 μm, greater than or equal to 15 μm, or greater than or equal to 20 μm. The thickness T may for example be less than or equal to 30 μm, less than or equal to 50 μm, less than or equal to 70 μm, or less than or equal to 100 μm. The thickness T may fall within a range defined by a first group consisting of 8 μm, 10 μm, 15 μm, or 20 μm and/or a second group consisting of 30 μm, 50 μm, 70 μm, and 100 μm. The thickness T may fall within a range defined by a combination of any one of the values included in the aforementioned first group and any one of the values included in the aforementioned second group. The thickness T may fall within a range defined by a combination of any two of the values included in the aforementioned first group. The thickness T may fall within a range defined by a combination of any two of the values included in the aforementioned second group. The thickness T may for example be greater than or equal to 8 μm and less than or equal to 100 μm, greater than or equal to 8 μm and less than or equal to 70 μm, greater than or equal to 8 μm and less than or equal to 50 μm, greater than or equal to 8 μm and less than or equal to 30 μm, greater than or equal to 8 μm and less than or equal to 20 μm, greater than or equal to 8 μm and less than or equal to 15 μm, greater than or equal to 8 μm and less than or equal to 10 μm, greater than or equal to 10 μm and less than or equal to 100 μm, greater than or equal to 10 μm and less than or equal to 70 μm, greater than or equal to 10 μm and less than or equal to 50 μm, greater than or equal to 10 μm and less than or equal to 30 μm, greater than or equal to 10 μm and less than or equal to 20 μm, greater than or equal to 10 μm and less than or equal to 15 μm, greater than or equal to 15 μm and less than or equal to 100 μm, greater than or equal to 15 μm and less than or equal to 70 μm, greater than or equal to 15 μm and less than or equal to 50 μm, greater than or equal to 15 μm and less than or equal to 30 μm, greater than or equal to 15 μm and less than or equal to 20 μm, greater than or equal to 20 μm and less than or equal to 100 μm, greater than or equal to 20 μm and less than or equal to 70 μm, greater than or equal to 20 μm and less than or equal to 50 μm, greater than or equal to 20 μm and less than or equal to 30 μm, greater than or equal to 30 μm and less than or equal to 100 μm, greater than or equal to 30 μm and less than or equal to 70 μm, greater than or equal to 30 μm and less than or equal to 50 μm, greater than or equal to 50 μm and less than or equal to 100 μm, greater than or equal to 50 μm and less than or equal to 70 μm, or greater than or equal to 70 μm and less than or equal to 100 μm.

Making the thickness T less than or equal to 100 μm makes it possible to restrain the deposited material 7 from adhering to wall surfaces of the through holes 53. This makes it possible to increase efficiency In the use of the deposited material 7. Further, making the thickness T less than or equal to 8 μm makes it possible to restrain the mask 50 from becoming damaged.

As a method for measuring the thickness T, a contact measurement method is employed. The contact measurement method involves the use of a HEIDENHAIN's length gauge HEIDENHAIN-METRO “MT1271”, which includes a plunger of a ball bush guide type.

The metal plate 60 may be made of a magnetic material. For example, the metal plate 60 may be made of an iron alloy containing nickel. The iron alloy may further contain cobalt in addition to nickel. For example, the total nickel and cobalt content may be higher than or equal to 28 mass % and lower than or equal to 54 mass %, and the cobalt content may be higher than or equal to 0 mass % and lower than or equal to 6 mass %.

The total nickel and cobalt content of the metal plate 60 may be higher than or equal to 28 mass % and lower than or equal to 38 mass %. Examples of such iron alloys include an Invar material, a Super-Invar material, and an Ultra-Invar material. The Invar material is an iron alloy containing 34 mass % or higher and 38 mass % or lower of nickel, remnant iron, and unavoidable impurities. The Super-Invar material is an iron alloy containing 30 mass % or higher and 34 mass % or lower of nickel, remnant iron, and unavoidable impurities. The Ultra-Invar material is an iron alloy containing 28 mass % or higher and 34 mass % or lower of nickel, 2 mass % or higher and 7 mass % or lower of cobalt, 0.1 mass % or higher and 1.0 mass % or lower of manganese, 0.10 mass % or lower of silicon, 0.01 mass % or lower of carbon, remnant iron, and unavoidable impurities.

The total nickel and cobalt content of the metal plate 60 may be higher than or equal to 38 mass % and lower than or equal to 54 mass %. Examples of such iron alloys include a Fe—NI plated alloy. The Fe—Ni plated alloy is an iron alloy containing 38 mass % or higher and 54 mass % or lower of nickel, remnant iron, and unavoidable impurities.

The metal plate 60 may be made of an iron alloy other the aforementioned nickel-containing iron alloys. For example, the metal plate 60 may be made of a chromium-containing iron alloy. Examples of such iron alloys include stainless steel. The metal plate 60 may be made of a material other than an iron alloy. For example, the metal plate 60 may be made of a material such as nickel or a nickel-cobalt alloy.

An example of a method for manufacturing a metal plate 60 is described. Further, a parent material 64 for a metal plate is prepared. The parent material 64 is fabricated by dissolving a raw material in a melting furnace. After the parent material 64 has been taken out from the melting furnace, a grinding step of smoothing out a surface of the parent material 64 may be executed.

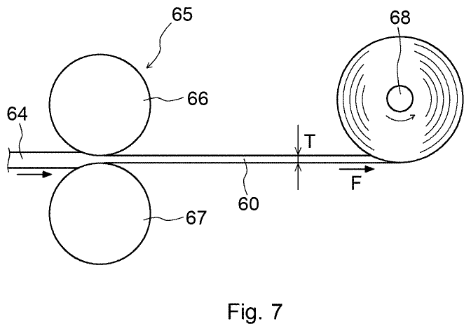

Then, as shown in FIG. 7, a rolling step of rolling the parent material 64 is executed. For example, the parent material 64 is conveyed in a direction F toward a rolling apparatus 65 while tension is being applied to the parent material 64. The rolling apparatus 65 includes a pair of work rolls 66 and 67. The parent material 64 is rolled by the pair of work rolls 66 and 67. This reduces the thickness of the parent material 64. Further, the parent material 64 is stretched along the direction F. This gives a metal plate 60 that extends in the direction F and that has a predetermined thickness T. The direction F in which the metal plate 60 extends is also referred to as “rolling direction F”. The rolling direction F may be parallel with the x direction of the mask 50.

The rolling step may include a hot-rolling step, a cold-rolling step, or other steps. A thermal processing step of heating the metal plate 60 may be executed between the hot-rolling step and the cold-rolling step. The rolling step may be followed by an annealing step.

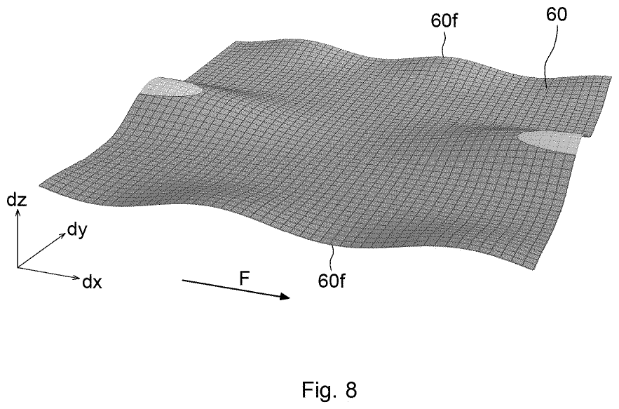

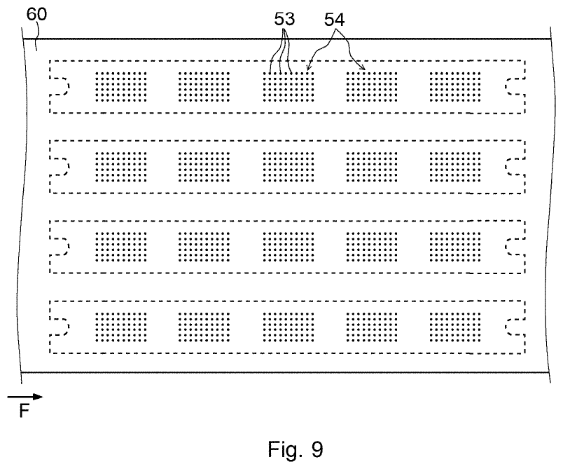

The metal plate 60 may become distorted in a case where degrees of deformation attributed to rolling vary from position to position. For example, as shown in FIG. 8, the metal plate 60 may have a corrugated shape. In the example shown in FIG. 8, the metal plate 60 has corrugated shapes appearing at side edges 60f. A corrugated shape along the x direction dx is formed due to a distortion of the metal plate 60 in the x direction. For example, the corrugated shape along the x direction dx is formed because lengths in the x direction dx vary from position to position in the y direction dy. As shown in FIG. 8, a corrugated shape along the y direction dy may appear. The corrugated shape along the y direction dy is formed due to a distortion of the metal plate 60 in the y direction.

An example of a method for manufacturing a mask 50 using a metal plate 60 is described. First, resist films are provided on the front surface 61 and back surface 62 of the metal plate 60. Then, the resist films are exposed and developed. This causes a first resist pattern to be formed on the front surface 61, and causes a second resist pattern to be formed on the back surface 62. The first resist pattern and the second resist pattern include openings that correspond to the through holes 53.

After that, the front surface 61 is etched with an etchant. This causes concave portions such as the first concave portions 531 to be formed in the front surface 61. Then, the back surface 62 is etched with an etchant. This causes concave portions such as the second concave portions 532 to be formed in the back surface 62. The concave portions in the front surface 61 and the concave portions in the back surface 62 are connected, whereby the through holes 53 are formed.

FIG. 9 is a plan view showing an example of a metal plate 60 having through holes 53 formed therein. A mask 50 is obtained by cutting out regions indicated by dotted lines from the metal plate 60.

As shown in FIG. 9, the regions indicated by the dotted lines may extend in the rolling direction F. That is, the x direction dx may be parallel with the rolling direction F. As shown in FIG. 9, two or more masks 50 may be cut out from the metal plate 60 in a direction orthogonal to the rolling direction F. In FIG. 9, corrugated shapes attributed to distortions of the metal plate 60 are omitted.

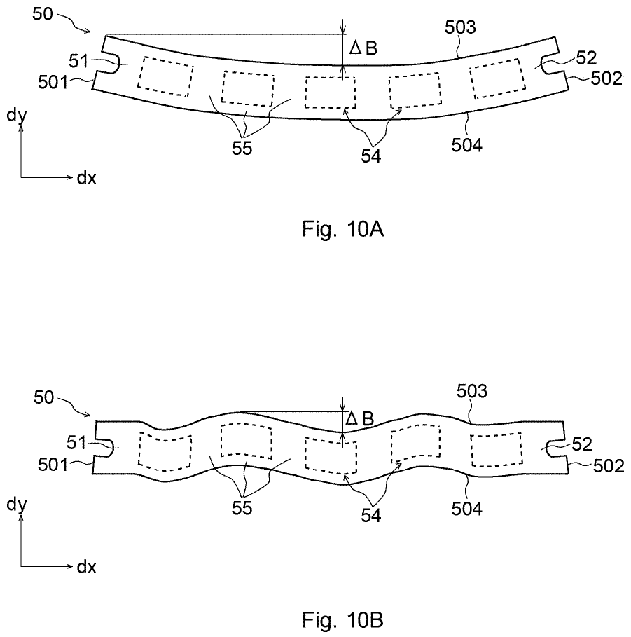

FIG. 10A is a plan view showing an example of a mask 50 taken out from a metal plate 60. The mask 50 may exhibit a shape attributed to a distortion of the metal plate 60. In the example shown in FIG. 10A, the mask 50 has a shape appearing at the third end 503 and the fourth end 504 to be convexly curved in a direction from the third end 503 toward the fourth end 504. Such a curved shape is also referred to as “C shape”.

FIG. 10B is a plan view showing an example of a mask 50 taken out from a metal plate 60. A distortion occurring in the mask 50 shown in FIG. 10B includes more higher-order components than a distortion occurring in the mask 50 shown in FIG. 10A. In other words, the distortion occurring in the mask 50 shown in FIG. 10A includes more lower-order components than the distortion occurring in the mask 50 shown in FIG. 10B. The phrase “more lower-order components” means that a distortion that occurs in a mask 50 includes many large-period waves in a case where the distortion is construed as a group of waves of various periods that appear in the x direction dx. The phrase “more higher-order components” means that the distortion includes many small-period waves.

In each of FIGS. 10A and 10B, reference sign ΔB denotes the maximum value of a difference in position of the mask 50 in the y direction dy. In each of the examples shown in FIGS. 10A and 10B, ΔB is calculated based on the position of the third end 503 in the y direction dy. As will be mentioned later, ΔB may be calculated based on the coordinates of a plurality of reference points located in the center of the mask 50 in the y direction dy and arranged in the x direction dx. AB represents the linearity of the mask 50 in the x direction dx.

As mentioned above, to a mask 50 fixed to the frame 41, tension is being applied in the x direction dx. For this reason, the linearity of a mask 50 fixed to the frame 41 is higher than the linearity of the masks 50 shown in FIGS. 10A and 10B.

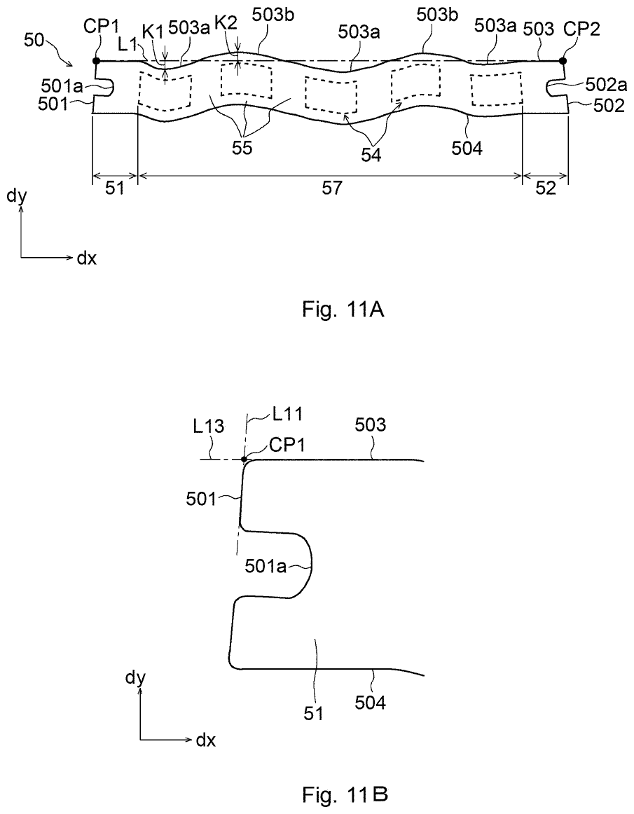

A configuration of a mask 50 with higher-order component distortion is described in detail with reference to FIG. 11A. The third end 503 of an intermediate portion 57 of the mask 50 may include at least one concave portion 503a and at least one convex portion 503b. In the example shown in FIG. 11A, the third end 503 of the intermediate portion 57 includes three concave portions 503a and two convex portions 503b. The intermediate portion 57 is a portion of the mask 50 located between the first end portion 51 and the second end portion 52 in planar view. The intermediate portion 57 may include two or more cells 54 arranged in the x direction dx. The intermediate portion 57 may be defined as a portion of the mask 50 in which multiple cells 54 are distributed in the x direction dx.

Each of the concave portions 503a is a portion of the third end 503 located further inward than a first straight line L1. Each of the convex portions 503b is a portion of the third end 503 located further outward than the first straight line L1. The term “inward” means “toward a cell 54 in the y direction”. The term “outward” means “away from a cell 54 in the y direction”. The first straight line L1 is an imaginary straight line connecting an eleventh cross point CP11 with a twenty-first cross point CP21. The eleventh cross point CP11 is a point of intersection of the first end 501 and the third end 503. The twenty-first cross point CP21 is a point of intersection of the second end 502 and the third end 503.

The eleventh cross point CP11 is described in detail with reference to FIG. 11B. The eleventh cross point CP11 may be a cross point of an imaginary straight line 11 that approximates the first end 501 and an imaginary straight line L13 that approximates the third end 503 of the first end portion 51. As shown in FIGS. 11A and 11B, the first end 501 may have one or more notches 501a formed therein.

Although not illustrated, the twenty-first cross point CP21 too may be a cross point of an imaginary straight line that approximates the second end 502 and an imaginary straight line that approximates the third end 503 of the second end portion 52. As shown in FIG. 11A, the second end 502 may have one or more notches 502a formed therein.

Each of the concave portions 503a has a depth K1. The depth K1 is the maximum value of the distance between the concave portion 503a and the first straight line L1 in the y direction. The depth K1 may for example be greater than or equal to 0.5 μm, greater than or equal to 1.0 μm, greater than or equal to 2.0 μm, or greater than or equal to 4.0 μm. The depth K1 may for example be less than or equal to 7.0 μm, less than or equal to 10.0 μm, less than or equal to 20.0 μm, or less than or equal to 35.0 μm. The depth K1 may fall within a range defined by a first group consisting of 0.5 μm, 1.0 μm, 2.0 μm, and 4.0 μm and/or a second group consisting of 7.0 μm, 10.0 μm, 20.0 μm, and 35.0 μm. The depth K1 may fall within a range defined by a combination of any one of the values included in the aforementioned first group and any one of the values included in the aforementioned second group. The depth K1 may fall within a range defined by a combination of any two of the values included in the aforementioned first group. The depth K1 may fall within a range defined by a combination of any two of the values included in the aforementioned second group. The depth K1 may for example be greater than or equal to 0.5 μm and less than or equal to 35.0 μm, greater than or equal to 0.5 μm and less than or equal to 20.0 μm, greater than or equal to 0.5 μm and less than or equal to 10.0 μm, greater than or equal to 0.5 μm and less than or equal to 7.0 μm, greater than or equal to 0.5 μm and less than or equal to 4.0 μm, greater than or equal to 0.5 μm and less than or equal to 2.0 μm, greater than or equal to 0.5 μm and less than or equal to 1.0 μm, greater than or equal to 1.0 μm and less than or equal to 35.0 μm, greater than or equal to 1.0 μm and less than or equal to 20.0 μm, greater than or equal to 1.0 μm and less than or equal to 10.0 μm, greater than or equal to 1.0 μm and less than or equal to 7.0 μm, greater than or equal to 1.0 μm and less than or equal to 4.0 μm, greater than or equal to 1.0 μm and less than or equal to 2.0 μm, greater than or equal to 2.0 μm and less than or equal to 35.0 μm, greater than or equal to 2.0 μm and less than or equal to 20.0 μm, greater than or equal to 2.0 μm and less than or equal to 10.0 μm, greater than or equal to 2.0 μm and less than or equal to 7.0 μm, greater than or equal to 2.0 μm and less than or equal to 4.0 μm, greater than or equal to 4.0 μm and less than or equal to 35.0 μm, greater than or equal to 4.0 μm and less than or equal to 20.0 μm, greater than or equal to 4.0 μm and less than or equal to 10.0 μm, greater than or equal to 4.0 μm and less than or equal to 7.0 μm, greater than or equal to 7.0 μm and less than or equal to 35.0 μm, greater than or equal to 7.0 μm and less than or equal to 20.0 μm, greater than or equal to 7.0 μm and less than or equal to 10.0 μm, greater than or equal to 10.0 μm and less than or equal to 35.0 μm, greater than or equal to 10.0 μm and less than or equal to 20.0 μm, or greater than or equal to 20.0 μm and less than or equal to 35.0 μm.

Each of the convex portions 503b has a height K2. The height K2 is the maximum value of the distance between the convex portion 503b and the first straight line L1 in the y direction. The range of numerical values of the height K2 may be identical to the aforementioned range of numerical values of the depth K1 of each of the concave portions 503a.

The depth K1 and the height K2 are measured with no tension being applied to the mask 50.

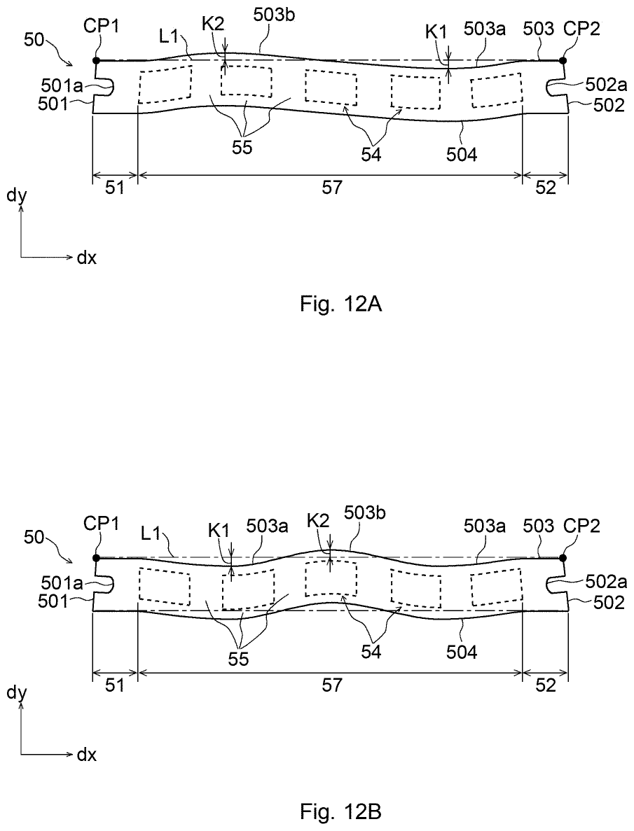

FIG. 12A is a plan view showing an example of a mask 50 with higher-order component distortion. In the example shown in FIG. 12A, the third end 503 of the intermediate portion 57 includes one concave portion 503a and one convex portion 503b.

FIG. 12B is a plan view showing an example of a mask 50 with higher-order component distortion. In the example shown in FIG. 12B, the third end 503 of the intermediate portion 57 includes two concave portions 503a and one convex portion 503b. Although not Illustrated, the third end 503 of the intermediate portion 57 may include one concave portion 503a and two convex portions 503b.

The third end 503 of the intermediate portion 57 of a mask 50 having a C shape shown in FIG. 10A either includes one concave portion 503a and does not include a convex portion 503b or includes one convex portion 503b and does not include a concave portion 503a. Meanwhile, the third end 503 of the intermediate portion 57 of a mask 50 including many higher-order component distortions as shown in FIG. 10B may include at least one concave portion 503a and at least one convex portion 503b.

The total number N of concave portions 503a and convex portions 503b that are included In the third end 503 of the intermediate portion 57 may for example be greater than or equal to 2, greater than or equal to 3, or greater than or equal to 4. The total number N may for example be less than or equal to 5, less than or equal to 10, or less than or equal to 20. The total number N may fall within a range defined by a first group consisting of 2, 3, and 4 and/or a second group consisting of 5, 10 and 20. The total number N may fall within a range defined by a combination of any one of the values included in the aforementioned first group and any one of the values included in the aforementioned second group. The total number N may fall within a range defined by a combination of any two of the values included in the aforementioned first group. The total number N may fall within a range defined by a combination of any two of the values included in the aforementioned second group. The total number N may for example be greater than or equal to 2 and less than or equal to 20, greater than or equal to 2 and less than or equal to 10, greater than or equal to 2 and less than or equal to 5, greater than or equal to 2 and less than or equal to 4, greater than or equal to 2 and less than or equal to 3, greater than or equal to 3 and less than or equal to 20, greater than or equal to 3 and less than or equal to 10, greater than or equal to 3 and less than or equal to 5, greater than or equal to 3 and less than or equal to 4, greater than or equal to 4 and less than or equal to 20, greater than or equal to 4 and less than or equal to 10, greater than or equal to 4 and less than or equal to 5, greater than or equal to 5 and less than or equal to 20, greater than or equal to 5 and less than or equal to 10, or greater than or equal to 10 and less than or equal to 20.

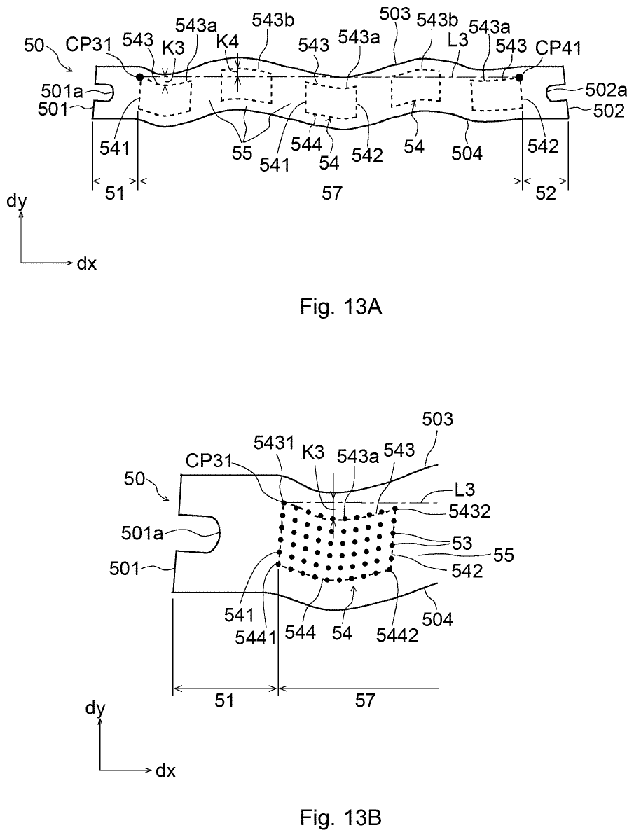

Each of FIGS. 11A and 11B has shown an example in which the shape of a mask 50 with higher-order component distortion is defined based on deformation of the third end 503. Each of FIGS. 13A and 13B illustrates an example in which the shape of a mask 50 with higher-order component distortion is defined based on deformation of the contours of a cell 54. As shown in FIG. 138, the contours of a cell 54 is constituted by an imaginary line passing through the center points of through holes 53 that are in contact with the first end portion 51, the second end portion 52, or the surrounding region 55.

FIG. 13A is a plan view showing an example of a mask 50 with higher-order component distortion. FIG. 13B is an enlarged plan view of the first end portion 51 and one cell 54 of the mask 50 of FIG. 13A. The cell 54 of the mask 50 may Include a cell first contour 541, a cell second contour 542, a cell third contour 543, and a cell fourth contour 544. The cell third contour 543 is a contour of the cell 54 that extends along the third end 503. The cell fourth contour 544 is a contour of the cell 54 that extends along the fourth end 504. The cell first contour 541 is a contour of the cell 54 that extends from a cell first end 5431 of the cell third contour 543 to a cell first end 5441 of the cell fourth contour 544. The cell second contour 542 is a contour of the cell 54 that extends from a cell second end 5432 of the cell third contour 543 to a cell second end 5442 of the cell fourth contour 544.

The cell first end 5431 of the cell third contour 543 is an end of the cell third contour 543 located toward the first end portion 51. The ell second end 5432 of the cell third contour 543 is an end of the cell third contour 543 located toward the second end portion 52. The cell first end 5441 of the cell fourth contour 544 is an end of the cell fourth contour 544 located toward the first end portion 51. The cell second end 5442 of the cell fourth contour 544 is an end of the cell fourth contour 544 located toward the second end portion 52.

The cell third contours 543 of one or more cells 54 included in the Intermediate portions 57 of the mask 50 may include at least one inner portion 543a and at least one outer portion 543b. In the example shown in FIG. 13A, the five cells 54 include three cell third contours 543 composed of inner portions 543a and two cell third contours 543 composed of outer portions 543b.

Each of the inner portions 543a is a portion of the corresponding one of the cell third contours 543 located further inward than a third straight line L3. Each of the outer portions 543b is a portion of the corresponding one of the cell third contours 543 located further outward than the third straight line L3. The term “inward” means “toward the center point of a cell 54 in the y direction”. The term “outward” means “away from the center point of a cell 54 in the y direction”. The third straight line L3 is an imaginary straight line connecting a thirty-first cross point CP31 with a forty-first cross point CP41. The thirty-first cross point CP31 is a point of intersection of the cell first contour 541 and the cell third contour 543 of a cell 54 that is closest to the first end portion 51. The forty-first cross point CP41 is a point of intersection of the cell second contour 542 and the cell third contour 543 of a cell 54 that is closest to the second end portion 52.

Each of the inner portions 543a has a clearance K3. The clearance K3 is the maximum value of the distance between the inner portion 543a and the third straight line L3 in the y direction. The clearance K3 may for example be greater than or equal to 0.5 μm, greater than or equal to 1.0 μm, greater than or equal to 2.0 μm, or greater than or equal to 4.0 μm. The clearance K3 may for example be less than or equal to 7.0 μm, less than or equal to 10.0 μm, less than or equal to 20.0 μm, or less than or equal to 35.0 μm. The clearance K3 may fall within a range defined by a first group consisting of 0.5 μm, 1.0 μm, 2.0 μm, and 4.0 μm and/or a second group consisting of 7.0 μm, 10.0 μm, 20.0 μm, and 35.0 μm. The clearance K3 may fall within a range defined by a combination of any one of the values included in the aforementioned first group and any one of the values included In the aforementioned second group. The clearance K3 may fall within a range defined by a combination of any two of the values included in the aforementioned first group. The clearance K3 may fall within a range defined by a combination of any two of the values included in the aforementioned second group. The clearance K3 may for example be greater than or equal to 0.5 μm and less than or equal to 35.0 μm, greater than or equal to 0.5 μm and less than or equal to 20.0 μm, greater than or equal to 0.5 μm and less than or equal to 10.0 μm, greater than or equal to 0.5 μm and less than or equal to 7.0 μm, greater than or equal to 0.5 μm and less than or equal to 4.0 μm, greater than or equal to 0.5 μm and less than or equal to 2.0 μm, greater than or equal to 0.5 μm and less than or equal to 1.0 μm, greater than or equal to 1.0 μm and less than or equal to 35.0 μm, greater than or equal to 1.0 μm and less than or equal to 20.0 μm, greater than or equal to 1.0 μm and less than or equal to 10.0 μm, greater than or equal to 1.0 μm and less than or equal to 7.0 μm, greater than or equal to 1.0 μm and less than or equal to 4.0 μm, greater than or equal to 1.0 μm and less than or equal to 2.0 μm, greater than or equal to 2.0 μm and less than or equal to 35.0 μm, greater than or equal to 2.0 μm and less than or equal to 20.0 μm, greater than or equal to 2.0 μm and less than or equal to 10.0 μm, greater than or equal to 2.0 μm and less than or equal to 7.0 μm, greater than or equal to 2.0 μm and less than or equal to 4.0 μm, greater than or equal to 4.0 μm and less than or equal to 35.0 μm, greater than or equal to 4.0 μm and less than or equal to 20.0 μm, greater than or equal to 4.0 μm and less than or equal to 10.0 μm, greater than or equal to 4.0 μm and less than or equal to 7.0 μm, greater than or equal to 7.0 μm and less than or equal to 35.0 μm, greater than or equal to 7.0 μm and less than or equal to 20.0 μm, greater than or equal to 7.0 μm and less than or equal to 10.0 μm, greater than or equal to 10.0 μm and less than or equal to 35.0 μm, greater than or equal to 10.0 μm and less than or equal to 20.0 μm, or greater than or equal to 20.0 μm and less than or equal to 35.0 μm.

Each of the outer portions 543b has a clearance K4. The clearance K4 is the maximum value of the distance between the outer portion 543b and the third straight line L3 in the y direction. The range of numerical values of the clearance K4 may be identical to the aforementioned range of numerical values of the clearance K3 of each of the inner portions 543a.

The clearances K3 and K4 are measured with no tension being applied to the mask 50.

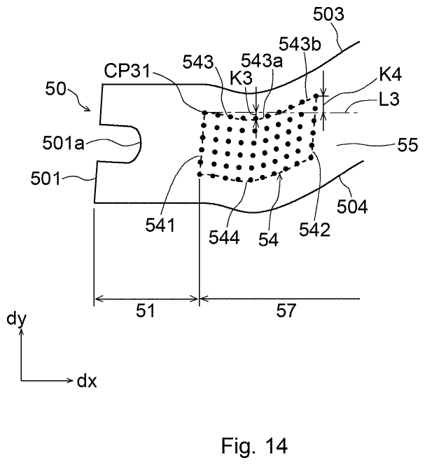

FIG. 14 is a plan view showing an example of a cell 54 of a mask 50 with higher-order component distortion. The cell third contour 543 of one cell 54 may include at least one inner portion 543a and at least one outer portion 543b. In the example shown in FIG. 14, the cell third contour 543 of one cell 54 includes one inner portion 543a and one outer portion 543b.

One or more cells 54 included in the intermediate portion 57 of a mask 50 having a C shape shown in FIG. 10A each either include only an inner portion 543a or include only an outer portion 543b. Meanwhile, one or more cells 54 included in the intermediate portion 57 of a mask 50 including many higher-order component distortions as shown in FIG. 10B may include at least one inner portion 543a and at least one outer portion 543b.

A method for manufacturing a mask 50 may include an inspection step of inspecting a mask 50 with reference to the linearity of the mask 50 before the mask 50 is fixed to the frame 41. This makes it possible to eliminate in advance a mask 50 that is less likely to have sufficient linearity when fixed to the frame 41. However, as will be mentioned later, the inspection step is insufficient in reliability of inspection when executed based solely on AB.

An example of a method for manufacturing a mask device 40 is described. First, a frame 41 is prepared. Then, alignment masks 50S are attached to the frame 41. An x-y coordinate system can be set based on the marks 56 of the alignment masks 50S.

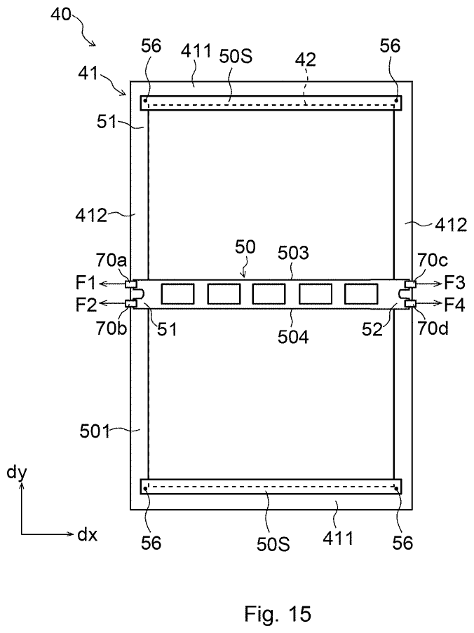

Then, an attaching step of attaching a mask 50 to the frame 41 is executed. For example, as shown in FIG. 15, tension is applied to the mask 50. After the position of the mask 50 has been adjusted in the x-y coordinate system, the first end portion 51 and second end portion 52 of the mask 50 are fixed to the second side regions 412 of the frame 41. For example, the first end portion 51 and the second end portion 52 are welded to the second side regions 412.

Clamps 70a to 70d may be used to apply tensions F1 to F4 to the mask 50. For example, the clamps 70a and 70b may be used to stretch the first end portion 51 outward in the x direction dx, and the clamps 70a and 70b may be used to stretch the second end portion 52 outward in the x direction dx. The term “outward” means “away from the opening 42”.

The attaching step may be executed while the second side regions 412 are being pressed inward in the x direction dx. In this case, after the mask 50 has been fixed to the second side regions 412, the second side regions 412 will elastically restore themselves outward in the x direction dx. For this reason, a tension that acts outward in the x direction dx can be applied to the mask 50 fixed to the second side regions 412. This makes it possible to restrain the mask 50 from deflecting.

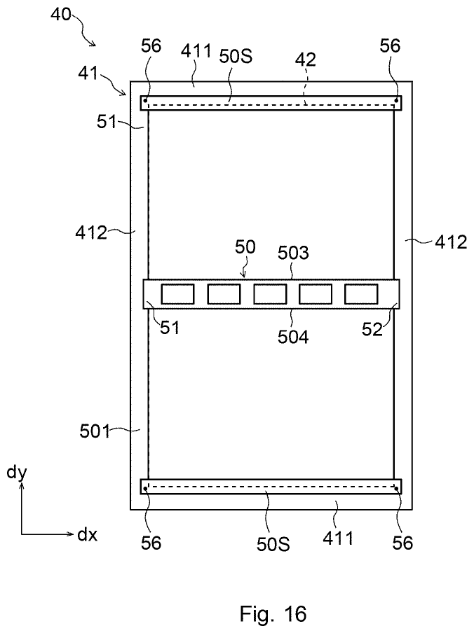

As shown in FIG. 16, the first end portion 51 and second end portion 52 of a mask 50 fixed to the second side regions 412 may be partially removed.

Attaching a plurality of masks 50 to the frame 41 in sequence gives the mask device 40 shown in FIG. 3.

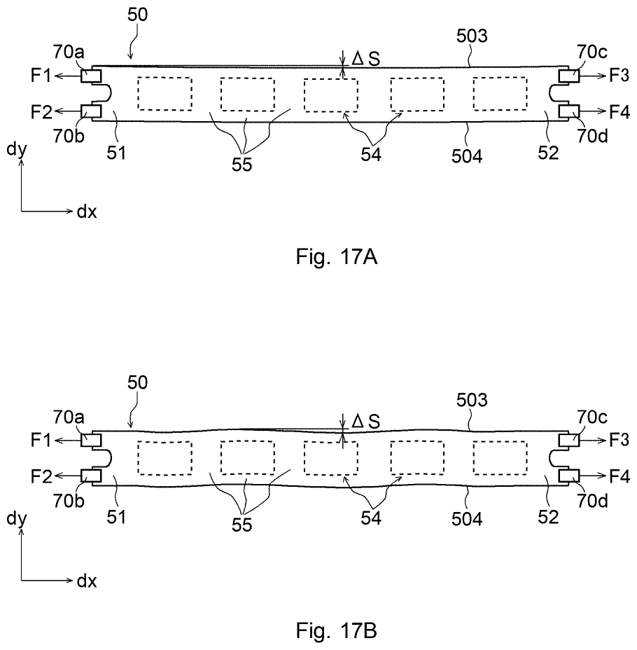

Distortions of masks 50 are reduced to some degree by applying tension to the masks 50. FIG. 17A is a plan view showing a state in which tension is being applied to the mask 50 shown in FIG. 10A. FIG. 17B is a plan view showing a state in which tension is being applied to the mask 50 shown in FIG. 10B. Reference sign ΔS denotes the maximum value of a difference in position of a mask 50 under tension in the y direction dy. ΔS is smaller than ΔB of each of FIGS. 10A and 10B.

The inventors found out, based on a study of masks 50, that the degree of the distortions reduced by applying tension to the masks 50 depends on the Individual masks 50. Further, the inventors also found out that a distortion including many higher-order components is more hardly reduced by tension than a distortion including many lower-order components like a C shape. For example, AB of the mask 50 shown in FIG. 10B is smaller than ΔB of the mask 50 shown in FIG. 10A. Meanwhile, ΔS of the mask 50 shown in FIG. 17B is smaller than ΔS of the mask 50 shown in FIG. 17A. That is, the distortion of the mask 50 shown in FIG. 10B is reduced to a smaller degree by tension than the distortion of the mask 50 shown in FIG. 10A. This suggests that an inspection of a mask 50 is insufficient in reliability of inspection when performed based solely on AB.

Further, the inventors also found out that it is preferable that a tension that is applied to masks 50 in measuring ΔS be adjusted according to the individual characteristics of the masks 50. An advantage of measuring ΔS with tension applied to a mask 50 is that the state of a mask 50 whose lower-order component distortion has been reduced to some degree can be predicted, i.e. that higher-order component distortion that the mask 50 includes can be predicted. However, relationships between tension and lower-order component distortion to be reduced vary according to the individual characteristics of masks 50. For this reason, in a case where ΔS of each mask 50 is measured based on a certain tension, some masks 50 may have their ΔS greatly affected by lower-order component distortion.

It is conceivable that reliability of inspection may be improved by setting a strict threshold for ΔS in the inspection step. However, this causes an increase in the ratio of masks 50 that are judged as defective products, leading to a reduction in the yield of masks 50.

To address such a problem, the applicant proposes inspecting a mask 50 using the after-mentioned simple amplitude converted value ΔC. In the present embodiment, a tension that is applied to a mask 50 is adjusted so that the simple amplitude converted value ΔC is less than or equal to a certain value. After that, ΔS is measured. This makes it possible to restrain ΔS from being affected by lower-order component distortion. The following describes an example of a method for Inspecting a mask 50.

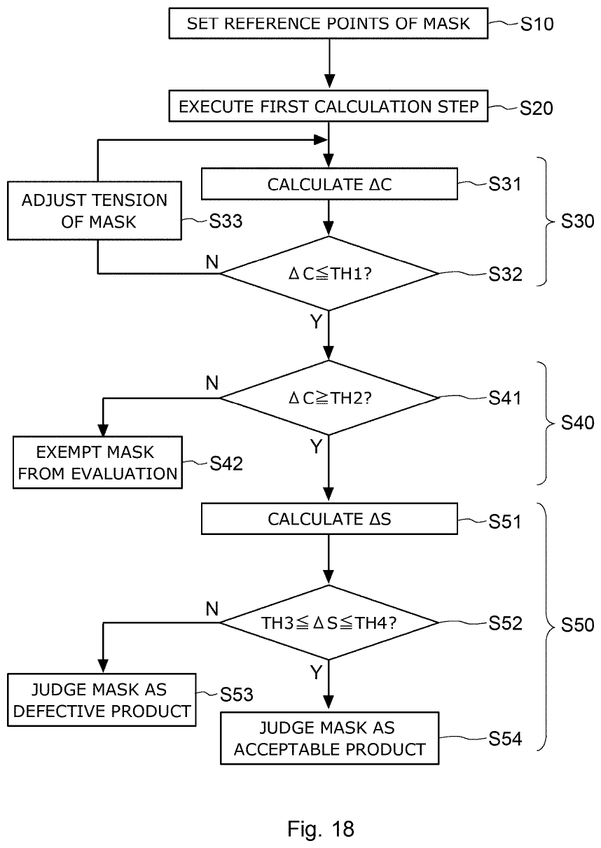

FIG. 18 is a flow chart showing an example of a method for Inspecting a mask 50. The method for inspecting a mask 50 may include a preparation step S10, a first calculation step S20, an adjustment step S30, and a second evaluation step S50. The method for inspecting a mask 50 may include a first evaluation step S40 that is executed between the adjustment step S30 and the second evaluation step S50.

The preparation step S10 may include a step of setting reference points of the mask 50. Based on the coordinates of the reference points, distortion, attitude, or other features of the mask 50 are evaluated.

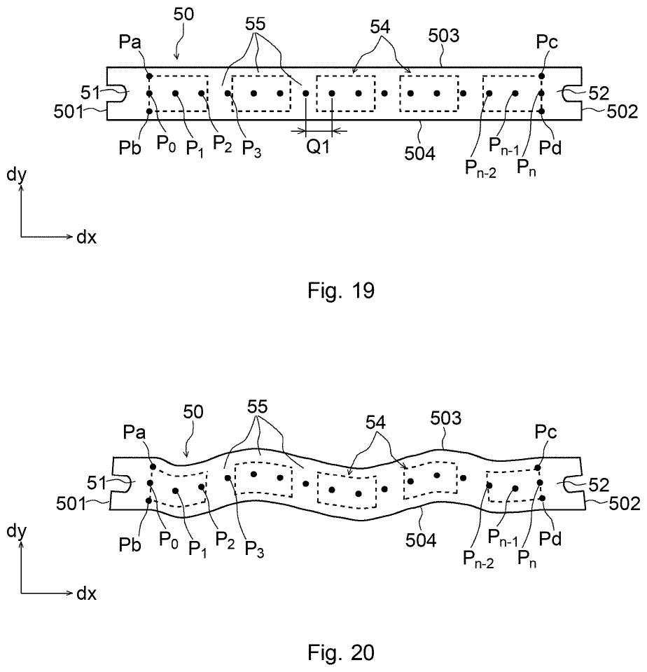

FIG. 19 is a plan view showing an example of a mask 50 with set reference points. In the example shown in FIG. 19, the mask 50 is not distorted with respect to the x direction dx or the y direction dy. For example, the third end 503 and fourth end 504 of the mask 50 linearly extend along the x direction dx from the first end portion 51 to the second end portion 52.

As shown in FIG. 19, the reference points may include n+1 reference points P₀ to Pₙ arranged in the x direction. n is a positive integer. The reference points P₀ to Pₙ may be arranged at equal spacings in the x direction dx. The reference points P₀ to Pₙ may be located in the center of the mask 50 in the y direction dy. The reference point P₀ may be a through hole 53 that is located in the center of the mask 50 in the y direction dy and that is closest to the first end portion 51. The reference point Pₙ may be a through hole 53 that is located in the center of the mask 50 in the y direction dy and that is closest to the second end portion 52.

The y coordinates of the reference points P₀ to Pₙ serve as indices of distortion occurring in the mask 50. As the distortion of the mask 50 becomes greater, a corrugated shape of greater amplitude appear at each position in the mask 50 in the x direction. For this reason, as the distortion of the mask 50 becomes greater, fluctuations in the y coordinates of the reference points P₀ to Pₙ become greater. As the distortion of the mask 50 becomes smaller, fluctuations in the y coordinates of the reference points P₀ to Pₙ become smaller. In the example shown in FIG. 19, the y coordinates of the reference points P₀ to Pₙ are constant.

The value of n may be set according to the accuracy required for the inspection step. n may for example be greater than or equal to 3, greater than or equal to 10, or greater than or equal to 20. n may for example be less than or equal to 30, less than or equal to 50, or less than or equal to 100. n may fall within a range defined by a first group consisting of 3, 10, and 20 and/or a second group consisting of 30, 50, and 100. n may fall within a range defined by a combination of any one of the values included in the aforementioned first group and any one of the values included in the aforementioned second group. n may fall within a range defined by a combination of any two of the values included in the aforementioned first group. n may fall within a range defined by a combination of any two of the values included in the aforementioned second group. n may for example be greater than or equal to 3 and less than or equal to 100, greater than or equal to 3 and less than or equal to 50, greater than or equal to 3 and less than or equal to 30, greater than or equal to 3 and less than or equal to 20, greater than or equal to 3 and less than or equal to 10, greater than or equal to 10 and less than or equal to 100, greater than or equal to 10 and less than or equal to 50, greater than or equal to 10 and less than or equal to 30, greater than or equal to 10 and less than or equal to 20, greater than or equal to 20 and less than or equal to 100, greater than or equal to 20 and less than or equal to 50, greater than or equal to 20 and less than or equal to 30, greater than or equal to 30 and less than or equal to 100, greater than or equal to 30 and less than or equal to 50, or greater than or equal to 50 and less than or equal to 100. n is for example 15.

Reference sign Q1 denotes the distance in the x direction dx between two reference points adjacent to each other in the x direction dx. Q1 may for example be greater than or equal to 10 mm, greater than or equal to 20 mm, or greater than or equal to 30 mm. Q1 may for example be less than or equal to 50 mm, less than or equal to 100 mm, or less than or equal to 200 mm. Q1 may fall within a range defined by a first group consisting of 10 mm, 20 mm, and 30 mm and/or a second group consisting of 50 mm, 100 mm, and 200 mm. Q1 may fall within a range defined by a combination of any one of the values included in the aforementioned first group and any one of the values included in the aforementioned second group. Q1 may fall within a range defined by a combination of any two of the values included in the aforementioned first group. Q1 may fall within a range defined by a combination of any two of the values included in the aforementioned second group. Q1 may for example be greater than or equal to 10 mm and less than or equal to 200 mm, greater than or equal to 10 mm and less than or equal to 100 mm, greater than or equal to 10 mm and less than or equal to 50 mm, greater than or equal to 10 mm and less than or equal to 30 mm, greater than or equal to 10 mm and less than or equal to 20 mm, greater than or equal to 20 mm and less than or equal to 200 mm, greater than or equal to 20 mm and less than or equal to 100 mm, greater than or equal to 20 mm and less than or equal to 50 mm, greater than or equal to 20 mm and less than or equal to 30 mm, greater than or equal to 30 mm and less than or equal to 200 mm, greater than or equal to 30 mm and less than or equal to 100 mm, greater than or equal to 30 mm and less than or equal to 50 mm, greater than or equal to 50 mm and less than or equal to 200 mm, greater than or equal to 50 mm and less than or equal to 100 mm, or greater than or equal to 100 mm and less than or equal to 200 mm.

As shown in FIG. 19, the reference points may include reference points Pa, Pb, Pc, and Pd for evaluating the degree of parallelization of the first end portion 51 and the second end portion 52. A smaller difference between the x coordinate of the reference point Pa and the x coordinate of the reference point Pb means the direction in which the first end 501 of the first end portion 51 extends is closer to the y direction dy. A smaller difference between the x coordinate of the reference point Pc and the x coordinate of the reference point Pd means the direction in which the second end 502 of the second end portion 52 extends is closer to the y direction dy.

The reference point Pa may be a through hole 53 that is closest to the first end 501 and that is closest to the third end 503. The reference point Pb may be a through hole 53 that Is closest to the first end 501 and that is closest to the fourth end 504. The reference point Pc may be a through hole 53 that is closest to the second end 502 and that is closest to the third end 503. The reference point Pd may be a through hole 53 that Is closest to the second end 502 and that is closest to the fourth end 504.

FIG. 20 is a plan view showing an example of a mask 50 with set reference points. In the example shown in FIG. 20, the mask 50 is distorted with respect to the x direction dx. For example, there are variations in the y coordinates of the reference points P₀ to Pₙ. For example, the x coordinate of the reference point Pa is different from the x coordinate of the reference point Pb. For example, the x coordinate of the reference point Pc is different from the x coordinate of the reference point Pd.

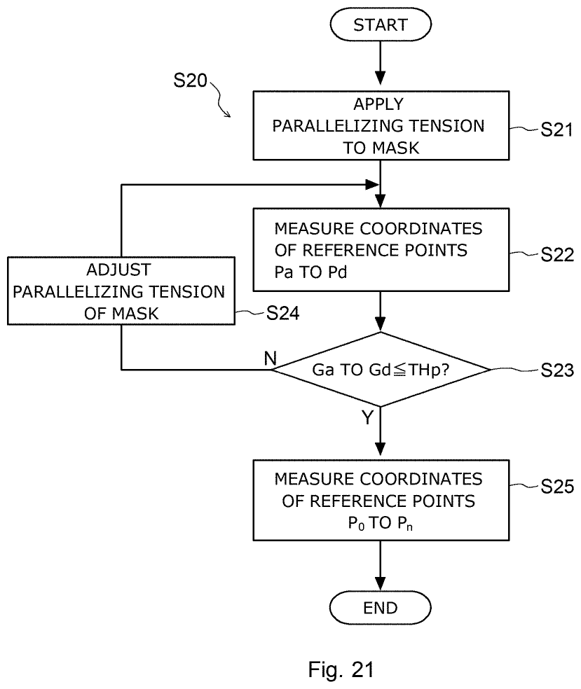

Next, the first calculation step S20 is described. FIG. 21 is a flow chart showing an example of the first calculation step S20. The first calculation step S20 may include a correction step of correcting the mask 50 so that the first end portion 51 and the second end portion 52 become parallel to each other. The correction step may include steps S21 to S24 shown in FIG. 18.

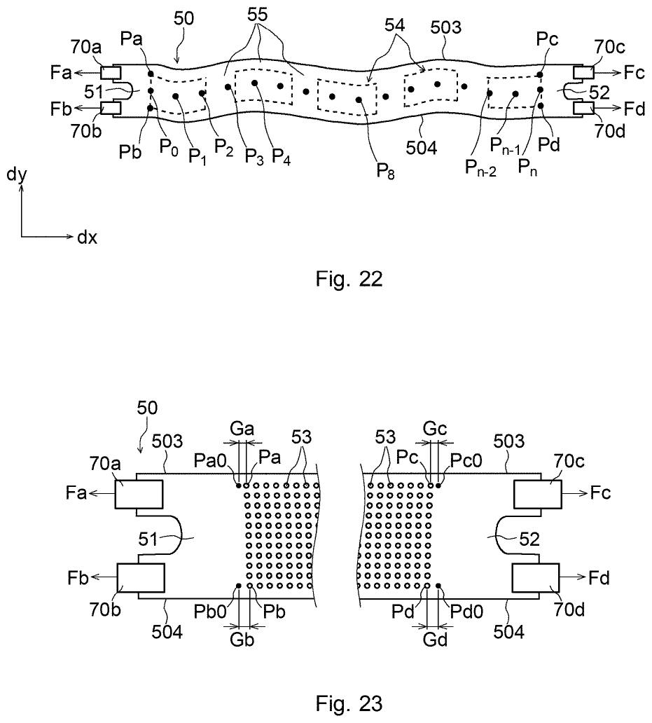

In the correction step, first, the step S21 of applying parallelizing tension to the mask 50 is executed. FIG. 22 is a plan view showing the mask 50 under parallelizing tension. The parallelizing tension may include Fa, Fb, Fc, and Fd. The parallelizing tension Fa may be a tension that is applied to the mask 50 via the clamp 70a fixed to the first end portion 51 so as to overlap the reference point Pa when seen along the x direction dx. The parallelizing tension Fb may be a tension that is applied to the mask 50 via the clamp 70b fixed to the first end portion 51 so as to overlap the reference point Pb when seen along the x direction dx. The parallelizing tension Fc may be a tension that is applied to the mask 50 via the clamp 70c fixed to the second end portion 52 so as to overlap the reference point Pc when seen along the x direction dx. The parallelizing tension Fd may be a tension that is applied to the mask 50 via the clamp 70d fixed to the second end portion 52 so as to overlap the reference point Pd when seen along the x direction dx.

The parallelizing tensions Fa, Fb, Fc, and Fd are set so that the mask 50 does not plastically deform. The parallelizing tensions Fa, Fb, Fc, and Fd are smaller than the tensions F1, F2, F3, and F4, which are applied to the mask 50 when the mask 50 is fixed to the frame 41. The initial values of the parallelizing tensions Fa, Fb, Fc, and Fd may for example be greater than or equal to 1 N, greater than or equal to 2 N, or greater than or equal to 3 N. The initial values of the parallelizing tensions Fa, Fb, Fc, and Fd may for example be less than or equal to 5 N, less than or equal to 10 N, or less than or equal to 20 N. The initial values of the parallelizing tensions Fa, Fb, Fc, and Fd may fall within a range defined by a first group consisting of 1 N, 2 N, and 3 N and/or a second group consisting of 5 N, 10 N, and 20 N. The initial values of the parallelizing tensions Fa, Fb, Fc, and Fd may fall within a range defined by a combination of any one of the values included in the aforementioned first group and any one of the values included in the aforementioned second group. The initial values of the parallelizing tensions Fa, Fb, Fc, and Fd may fall within a range defined by a combination of any two of the values included in the aforementioned first group. The initial values of the parallellzing tensions Fa, Fb, Fc, and Fd may fall within a range defined by a combination of any two of the values included in the aforementioned second group. The initial values of the parallelizing tensions Fa, Fb, Fc, and Fd may for example be greater than or equal to 1 N and less than or equal to 20 N, greater than or equal to 1 N and less than or equal to 10 N, greater than or equal to 1 N and less than or equal to 5 N, greater than or equal to 1 N and less than or equal to 3 N, greater than or equal to 1 N and less than or equal to 2 N, greater than or equal to 2 N and less than or equal to 20 N, greater than or equal to 2 N and less than or equal to 10 N, greater than or equal to 2 N and less than or equal to 5 N, greater than or equal to 2 N and less than or equal to 3 N, greater than or equal to 3 N and less than or equal to 20 N, greater than or equal to 3 N and less than or equal to 10 N, greater than or equal to 3 N and less than or equal to 5 N, greater than or equal to 5 N and less than or equal to 20 N, greater than or equal to 5 N and less than or equal to 10 N, or greater than or equal to 10 N and less than or equal to 20 N.

Then, the step S22 of measuring the coordinates of the reference points Pa, Pb, Pc, and Pd of the mask 50 with the parallelizing tensions Fa, Fb, Fc, and Fd applied thereto is executed. Then, as shown in FIG. 23, gaps Ga, Gb, Gc, and Gd are calculated. The gap Ga is the distance in the x direction dx between the reference point Pa and an ideal point Pa0. The gap Gb is the distance in the x direction dx between the reference point Pb and an ideal point Pb0. The gap Gc is the distance in the x direction dx between the reference point Pc and an ideal point Pc0. The gap Gd is the distance in the x direction dx between the reference point Pd and an ideal point Pd0.

The ideal points Pa0, Pb0, Pc0, and Pd0 correspond to the reference points Pa, Pb, Pc, and Pd in a case where the initial values of the parallelizing tensions Fa, Fb, Fc, and Fd are applied to an ideal mask 50. The ideal mask 50 is a mask 50, such as that shown in FIG. 19, that is not distorted with respect to the x direction dx or the y direction dy. The ideal points Pa0, Pb0, Pc0, and Pd0 are set based on the parallelizing tensions Fa, Fb, Fc, and Fd and the degree of stretching of the mask 50. The degree of stretching is the ratio of the amount of elastic extension of the mask 50 with respect to tension applied to the mask 50.

Then, the step S23 of determining whether the gaps Ga, Gb, Gc, and Gd are less than or equal to a threshold THp is executed. When the gaps Ga, Gb, Gc, and Gd are less than or equal to the threshold THp, it means that the first end portion 51 and the second end portion 52 are substantially parallel to each other. For example, it means that the angle formed by the direction in which the first end 501 extends and the direction in which the second end 502 extends Is less than or equal to 1 degree. In a case where the gaps Ga, Gb, Gc, and Gd are greater than the threshold THp, the step S24 of adjusting the parallelizing tensions Fa, Fb, Fc, and Fd is executed. Repeating the steps S22 to S24 makes it possible to make the gaps Ga, Gb, Gc, and Gd less than or equal to the threshold THp.

The threshold THp may for example be greater than or equal to 0.1 μm, greater than or equal to 0.2 μm, or greater than or equal to 0.3 μm. The threshold THp may for example be less than or equal to 0.5 μm, less than or equal to 0.7 μm, or less than or equal to 1.0 μm. The threshold THp may fall within a range defined by a first group consisting of 0.1 μm, 0.2 μm, and 0.3 μm and/or a second group consisting of 0.5 μm, 0.7 μm, and 1.0 μm. The threshold THp may fall within a range defined by a combination of any one of the values included in the aforementioned first group and any one of the values included in the aforementioned second group. The threshold THp may fall within a range defined by a combination of any two of the values included in the aforementioned first group. The threshold THp may fall within a range defined by a combination of any two of the values included in the aforementioned second group. The threshold THp may for example be greater than or equal to 0.1 μm and less than or equal to 1.0 μm, greater than or equal to 0.1 μm and less than or equal to 0.7 μm, greater than or equal to 0.1 μm and less than or equal to 0.5 μm, greater than or equal to 0.1 μm and less than or equal to 0.3 μm, greater than or equal to 0.1 μm and less than or equal to 0.2 μm, greater than or equal to 0.2 μm and less than or equal to 1.0 μm, greater than or equal to 0.2 μm and less than or equal to 0.7 μm, greater than or equal to 0.2 μm and less than or equal to 0.5 μm, greater than or equal to 0.2 μm and less than or equal to 0.3 μm, greater than or equal to 0.3 μm and less than or equal to 1.0 μm, greater than or equal to 0.3 μm and less than or equal to 0.7 μm, greater than or equal to 0.3 μm and less than or equal to 0.5 μm, greater than or equal to 0.5 μm and less than or equal to 1.0 μm, greater than or equal to 0.5 μm and less than or equal to 0.7 μm, or greater than or equal to 0.7 μm and less than or equal to 1.0 μm. The threshold THp is for example 0.5 μm.

After the gaps Ga, Gb, Gc, and Gd have become less than or equal to the threshold THp, the measuring step S25 of measuring the coordinates of the reference points P₀ to Pₙ is executed. The measuring step S25 is executed with the mask 50 corrected so that the first end portion 51 and the second end portion 52 become parallel to each other. The measuring step S25 includes at least measuring the y components y₀ to yₙ of the coordinates of the reference points P₀ to Pₙ. yᵢ denotes the y coordinate of a reference point Pᵢ. i is an integer that is greater than or equal to 0 and less than or equal to n. The measuring step S25 may include measuring the x components x₀ to xₙ of the coordinates of the reference points P₀ to Pₙ. The measuring step S25 may include measuring the z components of the coordinates of the reference points P₀ to Pₙ. The z components are coordinates in a z direction orthogonal to the x direction dx and the y direction dy.

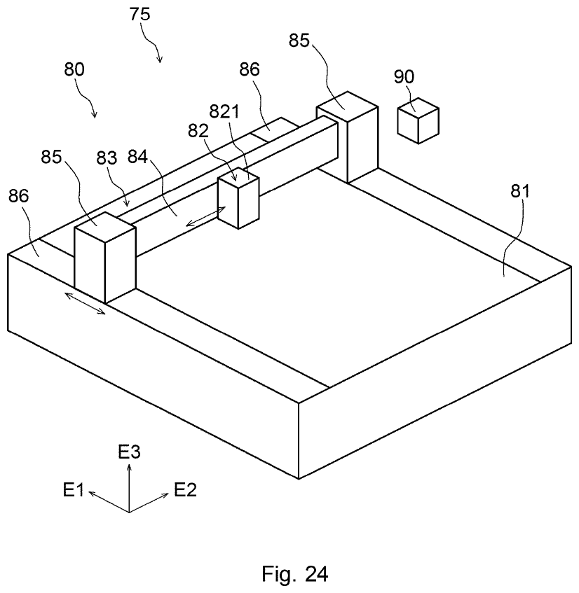

FIG. 24 is a diagram showing an example of an inspection apparatus 75 that executes the method for inspecting a mask 50. The inspection apparatus 75 includes a measuring device 80 that measures the coordinates of the reference points P₀ to Pₙ. The measuring device 80 may include a stage 81, an observation instrument 82, and a shifter 83.

The stage 81 is a stand on which an object to be inspected is placed. The stage 81 may have a surface constituted by a transparent material such as glass. A frame 41 to which alignment masks 50S and a mask 50 are attached may be placed on the stage 81.

The observation instrument 82 includes at least an optical receiver 821. The optical receiver 821 photographs the mask 50. The optical receiver 821 is for example a camera. The observation instrument 821 may include an optical transmitter. The optical transmitter emits light such as a laser toward the mask 50. In a case where the observation instrument 82 includes the optical transmitter, the optical receiver 821 may detect light emitted from the optical transmitter and reflected by the mask 50. Based on the light detected by the optical receiver 821, the marks 56 of the alignment masks 50S, the through holes 53 of the mask 50, contours, or other features are detected.

The shifter 83 causes the observation instrument 82 to move along an in-plane direction of the stage 81. The shifter 83 may include a second shifter 84, a pair of pillars 85, and a first shifter 86. The second shifter 84 may cause the observation instrument 82 to move along a second direction E2. The pair of pillars 85 may support the second shifter 84. The first shifter 86 may cause the pair of pillars 85 to move along a first direction E1. The second direction E2 may be orthogonal to the first direction E1. By the optical receiver 821 taking photographs at multiple positions in the first direction E1 and the second direction E2, the coordinates of the reference points P₀ to Pₙ of the mask 50, the coordinates of the reference points Pa, Pb, Pc, and Pd, or other coordinates are measured.

The inspection apparatus 75 may include a computer 90 such as a personal computer. The measuring device 80 may be controlled by the computer 90. Although not illustrated, the inspection apparatus 75 may include a correction device for executing the aforementioned correction step. The correction device includes, for example, the aforementioned clamps 70a to 70d, which apply tension to the mask 50. The clamps 70a to 70d may be controlled by the computer 90. The measuring device 80 and the correction device constitute a first calculation apparatus for executing the aforementioned first calculation step.

After the gaps Ga, Gb, Gc, and Gd have become less than or equal to the threshold THp, the adjustment step S30 is executed. The tension that is applied to the mask 50 is adjusted by the adjustment step S30 so that the simple amplitude converted value ΔC becomes less than or equal to a first threshold TH1. The tension adjusted by the adjustment step S30 is also referred to as “adjusted tension”.

In the adjustment step S30, as shown in FIG. 18, a step S31 of calculating the simple amplitude converted value ΔC Is executed. The simple amplitude converted value ΔC Is the amplitude of simple amplitude converted components y″₀ to y″ₙ that are generated by fitting the curved shape of the mask 50 to the shape of a cosine wave. The step of calculating the simple amplitude converted value ΔC is described.

First, a step of calculating the y components y′₀ to y′ₙ of a cosine function y′ that simulates a cosine wave is executed. Then, a step of calculating amplitude magnifications Y₀ to Yₙ by multiplying the y components y₀ to yₙ of the coordinates of the reference points P₀ to Pₙ by the y components y′₀ to y′ₙ. Yᵢ is expressed by the following formula:

Yᵢ=yᵢ×y′ᵢ

where i is an integer that is greater than or equal to 0 and less than or equal to n.

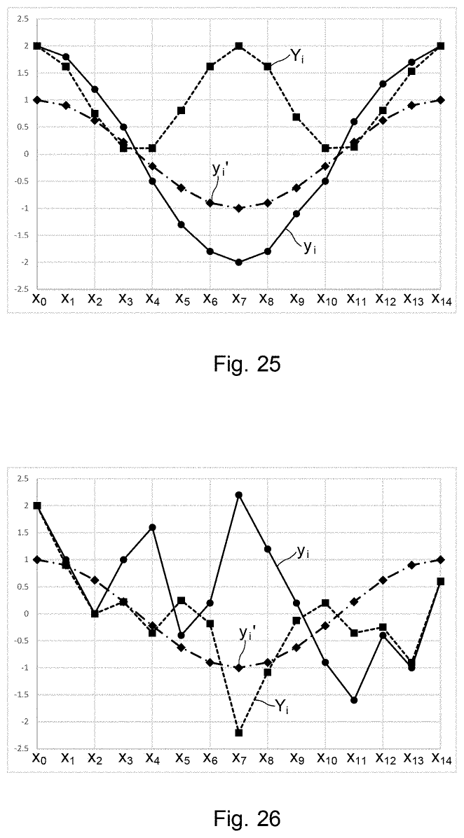

FIG. 25 is a graph showing examples of yᵢ, yᵢ′, and Yᵢ. The horizontal axis of the graph represents the x components of the coordinates of the reference points P₀ to Pₙ. The cosine function y′ has a phase that proceeds by approximately 2 n in a period from x₀ to xₙ. In the example shown in FIG. 25, the curved shape of the mask 50 as expressed by the y components y₀ to yₙ of the coordinates of the reference points P₀ to Pₙ is similar to the shape of a cosine wave.

FIG. 26 is a graph showing other examples of yᵢ, yᵢ′, and Yᵢ. In the example shown in FIG. 26, the curved shape of the mask 50 as expressed by the y components y₀ to yₙ of the coordinates of the reference points P₀ to Pₙ is not very similar to the shape of a cosine wave.

Then, a step of calculating an average amplitude magnification Mag.Y is executed. The average amplitude magnification Mag.Y is the average of the amplitude magnifications Y₀ to Yₙ. The average amplitude magnification Mag.Y is calculated by the following formula:

Mag.Y=(ΣYᵢ)/(n+1)

Then, a step of calculating the simple amplitude converted components y″₀ to y″ₙ by multiplying the average amplitude magnification Mag.Y by the y components y′₀ to y′ₙ of the cosine function y′ is executed. y″ᵢ is expressed by the following formula:

y″ᵢ=Mag.Y×y′ᵢ,

Then, the step of calculating the simple amplitude converted value ΔC is executed. The simple amplitude converted value ΔC is the difference between the maximum and minimum values of the simple amplitude converted components y″₀ to y″ₙ. In this way, the simple amplitude converted value ΔC is calculated.

As shown in FIG. 18, the step S31 is followed by a step S32 of determining whether the simple amplitude converted value ΔC is less than or equal to the first threshold TH1. The first threshold TH1 may for example be greater than or equal to 0.60 μm, greater than or equal to 0.80 μm, or greater than or equal to 1.00 μm. The first threshold TH1 may for example be less than or equal to 1.20 μm, less than or equal to 1.50 μm, or less than or equal to 2.00 μm. The first threshold TH1 may fall within a range defined by a first group consisting of 0.60 μm, 0.80 μm, and 1.00 μm and/or a second group consisting of 1.20 μm, 1.50 μm, and 2.00 μm. The first threshold TH1 may fall within a range defined by a combination of any one of the values included in the aforementioned first group and any one of the values included in the aforementioned second group. The first threshold TH1 may fall within a range defined by a combination of any two of the values included in the aforementioned first group. The first threshold TH1 may fall within a range defined by a combination of any two of the values included in the aforementioned second group. The first threshold TH1 may for example be greater than or equal to 0.60 μm and less than or equal to 2.00 μm, greater than or equal to 0.60 μm and less than or equal to 1.50 μm, greater than or equal to 0.60 μm and less than or equal to 1.20 μm, greater than or equal to 0.60 μm and less than or equal to 1.00 μm, greater than or equal to 0.60 μm and less than or equal to 0.80 μm, greater than or equal to 0.80 μm and less than or equal to 2.00 μm, greater than or equal to 0.80 μm and less than or equal to 1.50 μm, greater than or equal to 0.80 μm and less than or equal to 1.20 μm, greater than or equal to 0.80 μm and less than or equal to 1.00 μm, greater than or equal to 1.00 μm and less than or equal to 2.00 μm, greater than or equal to 1.00 μm and less than or equal to 1.50 μm, greater than or equal to 1.00 μm and less than or equal to 1.20 μm, greater than or equal to 1.20 μm and less than or equal to 2.00 μm, greater than or equal to 1.20 μm and less than or equal to 1.50 μm, or greater than or equal to 1.50 μm and less than or equal to 2.00 μm. The first threshold TH1 is for example 1.11 μm.

In a case where the simple amplitude converted value ΔC is greater than the first threshold TH1, a step S33 of adjusting the tension that is applied to the mask 50 is executed. In the step S33, the tension may be increased. This makes it possible to reduce the simple amplitude converted value ΔC with high probability. A tension at which the simple amplitude converted value ΔC has become less than or equal to the first threshold TH1 may be recorded as adjusted tension.

In the step S33, an upper limit on the tension may be set. This makes it possible to restrain the mask 50 from plastically deforming. The upper limit may be set as the ratio of a tension MF with respect to the cross-sectional area MS of the mask 50. The cross-sectional area MS may be set in a cross-section of the mask 50 orthogonal to the x direction dx. The tension MF is a force that is applied to the first end portion 51 in the x direction dx. In a case where forces F1 and F2 are applied to the first end portion 51 via two clamps 70a and 70b as shown in FIGS. 17A and 17B, the tension MF is the sum of the forces F1 and F2.

After the simple amplitude converted value ΔC has become equal to the first threshold TH1, the first evaluation step S40 may be executed as shown in FIG. 18.

In the first evaluation step S40, a step S41 of determining whether the simple amplitude converted value ΔC is greater than or equal to a second threshold TH2 is executed. The second threshold TH2 is smaller than the first threshold TH1. The second threshold TH2 may for example be greater than or equal to 0.05 μm, greater than or equal to 0.10 μm, or greater than or equal to 0.15 μm. The second threshold TH2 may for example be less than or equal to 0.30 μm, less than or equal to 0.35 μm, or less than or equal to 0.40 μm. The second threshold TH2 may fall within a range defined by a first group consisting of 0.05 μm, 0.10 μm, and 0.15 μm and/or a second group consisting of 0.30 μm, 0.35 μm, and 0.40 μm. The second threshold TH2 may fall within a range defined by a combination of any one of the values Included in the aforementioned first group and any one of the values included in the aforementioned second group. The second threshold TH2 may fall within a range defined by a combination of any two of the values included in the aforementioned first group. The second threshold TH2 may fall within a range defined by a combination of any two of the values included in the aforementioned second group. The second threshold TH2 may for example be greater than or equal to 0.05 μm and less than or equal to 0.40 μm, greater than or equal to 0.05 μm and less than or equal to 0.35 μm, greater than or equal to 0.05 μm and less than or equal to 0.30 μm, greater than or equal to 0.05 μm and less than or equal to 0.15 μm, greater than or equal to 0.05 μm and less than or equal to 0.10 μm, greater than or equal to 0.10 μm and less than or equal to 0.40 μm, greater than or equal to 0.10 μm and less than or equal to 0.35 μm, greater than or equal to 0.10 μm and less than or equal to 0.30 μm, greater than or equal to 0.10 μm and less than or equal to 0.15 μm, greater than or equal to 0.15 μm and less than or equal to 0.40 μm, greater than or equal to 0.15 μm and less than or equal to 0.35 μm, greater than or equal to 0.15 μm and less than or equal to 0.30 μm, greater than or equal to 0.30 μm and less than or equal to 0.40 μm, greater than or equal to 0.30 μm and less than or equal to 0.35 μm, or greater than or equal to 0.35 μm and less than or equal to 0.40 μm. The second threshold TH2 is for example 0.20 μm.

As shown as a step S42 in FIG. 18, in a case where the simple amplitude converted value ΔC is less than the second threshold TH2, the mask 50 may be exempted from evaluation. For example, the mask 50 may be judged as an accepted product. In a case where the simple amplitude converted value ΔC is less than the second threshold TH2, the mask 50 has sufficient linearity with high probability.

In a case where the simple amplitude converted value ΔC is greater than or equal to the second threshold TH2, the second evaluation step S50 is executed as shown in FIG. 18.

In the second evaluation step S50, first, a step S51 of calculating amplitude ΔS is executed. The amplitude ΔS is the amplitude of the mask 50 under adjusted tension. Specifically, the amplitude ΔS is the difference between the maximum and minimum values of the y components y₀ to yₙ of the reference points P₀ to Pₙ of the mask 50 under adjusted tension.

Then, a step S52 of determining whether the amplitude ΔS is greater than or equal to a third threshold TH3 and less than or equal to a fourth threshold TH4 is executed. The third threshold TH3 and the fourth threshold TH4 may be functions of the simple amplitude converted value ΔC. For example, the third threshold TH3 and the fourth threshold TH4 may be expressed by the following formulas:

TH3=1.8×ΔC+A3

TH4=1.8×ΔC+A4

where A3 is a constant and A4 is a constant that is greater than A3. When the amplitude ΔS is greater than or equal to the third threshold TH3 and less than or equal to the fourth threshold TH4, it suggests that there is a high possibility that the amplitude ΔS may have decreased as the simple amplitude converted value ΔC decreased. In a case where the amplitude ΔS is greater than or equal to the third threshold TH3 and less than or equal to the fourth threshold TH4, the mask 50 is judged as an acceptable product. In a case where the amplitude ΔS is less that the third threshold TH3 or in a case where the amplitude ΔS Is greater than the fourth threshold TH4, the mask 50 is judged as a defective product.

The constant A3 may for example be greater than or equal to 0.10 μm, greater than or equal to 0.20 μm, or greater than or equal to 0.30 μm. The constant A3 may for example be less than or equal to 0.50 μm, less than or equal to 0.60 μm, or less than or equal to 0.70 μm. The constant A3 may fall within a range defined by a first group consisting of 0.10 μm, 0.20 μm, and 0.30 μm and/or a second group consisting of 0.50 μm, 0.60 μm, and 0.70 μm. The constant A3 may fall within a range defined by a combination of any one of the values included in the aforementioned first group and any one of the values included in the aforementioned second group. The constant A3 may fall within a range defined by a combination of any two of the values included In the aforementioned first group. The constant A3 may fall within a range defined by a combination of any two of the values included In the aforementioned second group. The constant A3 may for example be greater than or equal to 0.10 μm and less than or equal to 0.70 μm, greater than or equal to 0.10 μm and less than or equal to 0.60 μm, greater than or equal to 0.10 μm and less than or equal to 0.50 μm, greater than or equal to 0.10 μm and less than or equal to 0.30 μm, greater than or equal to 0.10 μm and less than or equal to 0.20 μm, greater than or equal to 0.20 μm and less than or equal to 0.70 μm, greater than or equal to 0.20 μm and less than or equal to 0.60 μm, greater than or equal to 0.20 μm and less than or equal to 0.50 μm, greater than or equal to 0.20 μm and less than or equal to 0.30 μm, greater than or equal to 0.30 μm and less than or equal to 0.70 μm, greater than or equal to 0.30 μm and less than or equal to 0.60 μm, greater than or equal to 0.30 μm and less than or equal to 0.50 μm, greater than or equal to 0.50 μm and less than or equal to 0.70 μm, greater than or equal to 0.50 μm and less than or equal to 0.60 μm, or greater than or equal to 0.60 μm and less than or equal to 0.70 μm. The constant A3 is for example 0.40 μm.

The constant A4 may for example be greater than or equal to 1.50 μm, greater than or equal to 1.70 μm, or greater than or equal to 1.90 μm. The constant A4 may for example be less than or equal to 2.10 μm, less than or equal to 2.30 μm, or less than or equal to 2.50 μm. The constant A4 may fall within a range defined by a first group consisting of 1.50 μm, 1.70 μm, and 1.90 μm and/or a second group consisting of 2.10 μm, 2.30 μm, and 2.50 μm. The constant A4 may fall within a range defined by a combination of any one of the values included in the aforementioned first group and any one of the values included in the aforementioned second group. The constant A4 may fall within a range defined by a combination of any two of the values included In the aforementioned first group. The constant A4 may fall within a range defined by a combination of any two of the values included in the aforementioned second group. The constant A4 may for example be greater than or equal to 1.50 μm and less than or equal to 2.50 μm, greater than or equal to 1.50 μm and less than or equal to 2.30 μm, greater than or equal to 1.50 μm and less than or equal to 2.10 μm, greater than or equal to 1.50 μm and less than or equal to 1.90 μm, greater than or equal to 1.50 μm and less than or equal to 1.70 μm, greater than or equal to 1.70 μm and less than or equal to 2.50 μm, greater than or equal to 1.70 μm and less than or equal to 2.30 μm, greater than or equal to 1.70 μm and less than or equal to 2.10 μm, greater than or equal to 1.70 μm and less than or equal to 1.90 μm, greater than or equal to 1.90 μm and less than or equal to 2.50 μm, greater than or equal to 1.90 μm and less than or equal to 2.30 μm, greater than or equal to 1.90 μm and less than or equal to 2.10 μm, greater than or equal to 2.10 μm and less than or equal to 2.50 μm, greater than or equal to 2.10 μm and less than or equal to 2.30 μm, or greater than or equal to 2.30 μm and less than or equal to 2.50 μm.

The adjustment step S30, the first evaluation step S40, and the second evaluation step S50 may be executed by the computer 90 of the inspection apparatus 75. For example, the computer 90 may be installed with a program for causing the computer 90 to function as an adjustment device, a first evaluation device, and a second evaluation device. The adjustment device executes the adjustment step S30. For example, the adjustment device executes the steps S31 and S32 The adjustment device may control the clamps 70a to 70d so that the step S33 Is executed. The first evaluation device executes the first evaluation step S40. The second evaluation device executes the second evaluation step S50.

The program may be installed in advance in the computer before shipment of the computer or may be installed in the computer after shipment of the computer by utilizing a computer-readable non-transient storage medium having the program stored therein. The storage medium may be of any of various types such as a portable storage medium such as a magnetic disk or an optical disk or a fixed storage medium such as a hard disk device or a memory. Further, the program may be distributed through a communication line such as the Internet. In a case where the program is distributed via a communication line, a storage medium according to the present embodiment having the program stored therein is at least temporarily present in a distributing server.

In a step of manufacturing the mask device 40, a mask 50 judged as an acceptable product is used. The mask 50 can have high linearity when under tension. This makes it possible to increase the efficiency of the step of manufacturing the mask device 40. Increasing the linearity of the mask 50 makes it possible to increase the accuracy of position of the through holes of the mask 50. This makes it possible to increase the accuracy of position of a layer that is deposited on the substrate 110 via the mask 50.

In the present embodiment, as mentioned above, the mask 50 is inspected in consideration of the simple amplitude converted value ΔC as well as the amplitude ΔS of the mask 50. This makes it possible to restrain the positions of the through holes of the mask 50 from being misaligned from design positions when the mask 50 is fixed to the frame 41 under tension.

Various modifications can be added to the foregoing embodiment. The following describes other embodiments with reference to the drawings on an as-needed basis. In the following description and the drawings that are used in the following description, components that are configured in a manner similar to those of the foregoing embodiment are assigned signs identical to those assigned to the corresponding components of the foregoing embodiment, and a repeated description of such components is omitted. Further, in a case where it is obvious that working effects of the foregoing embodiment can be brought about by other embodiments too, a description of such working effects may be omitted.

The aforementioned embodiment has shown an example in which in the adjustment step S30, a tension is adjusted according to the result of a comparison between the simple amplitude converted value ΔC and the first threshold TH1. That is, the aforementioned embodiment has shown an example in which an adjusted tension is calculated as a result of feedback control. However, a method for calculating the adjusted tension is not limited to particular methods. For example, the adjusted tension may be calculated as a result of feedforward control.

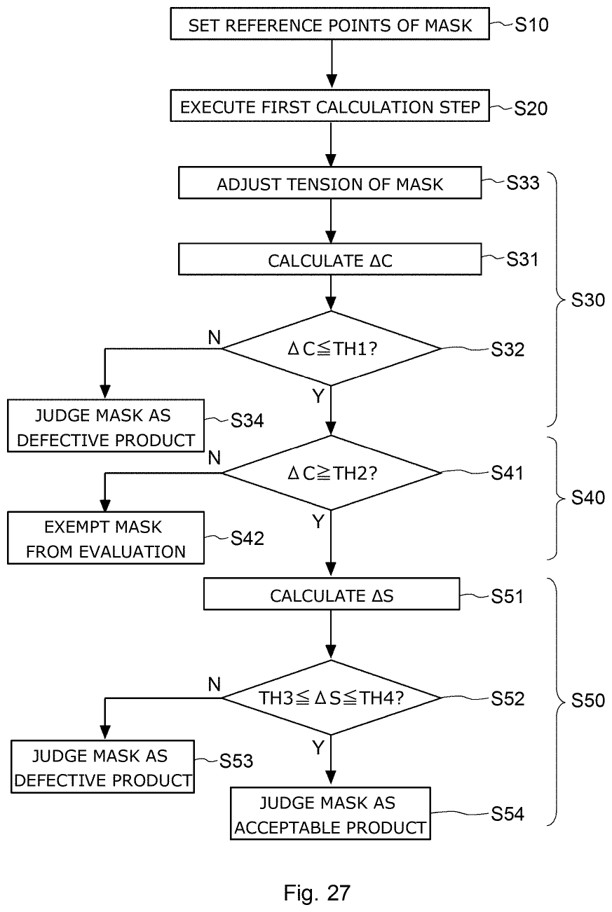

FIG. 27 is a flow chart showing an example of a method for inspecting a mask 50. As shown in FIG. 27, in the adjustment step S30, the determination step S32 may be preceded by the step S33 of adjusting the tension that is applied to the mask 50. The step S33 may include executing an adjustment algorithm installed in the adjustment device Including the clamps 70a to 70d.

The number of times that the adjustment algorithm is executed may for example be greater than or equal to 1, greater than or equal to 3, or greater than or equal to 6. The number of times that the adjustment algorithm is executed may for example be less than or equal to 8, less than or equal to 10, or less than or equal to 15. The number of times that the adjustment algorithm is executed may fall within a range defined by a first group consisting of 1, 3, and 6 and/or a second group consisting of 8, 10, and 15. The number of times that the adjustment algorithm is executed may fall within a range defined by a combination of any one of the values included in the aforementioned first group and any one of the values included in the aforementioned second group. The number of times that the adjustment algorithm is executed may fall within a range defined by a combination of any two of the values included in the aforementioned first group. The number of times that the adjustment algorithm Is executed may fall within a range defined by a combination of any two of the values included in the aforementioned second group. The number of times that the adjustment algorithm is executed may for example be greater than or equal to 1 and less than or equal to 15, greater than or equal to 1 and less than or equal to 10, greater than or equal to 1 and less than or equal to 8, greater than or equal to 1 and less than or equal to 6, greater than or equal to 1 and less than or equal to 3, greater than or equal to 3 and less than or equal to 15, greater than or equal to 3 and less than or equal to 10, greater than or equal to 3 and less than or equal to 8, greater than or equal to 3 and less than or equal to 6, greater than or equal to 6 and less than or equal to 15, greater than or equal to 6 and less than or equal to 10, greater than or equal to 6 and less than or equal to 8, greater than or equal to 8 and less than or equal to 15, greater than or equal to 8 and less than or equal to 10, or greater than or equal to 10 and less than or equal to 15. The number of times that the adjustment algorithm is executed is for example 6. These number of times may be the sum of the number of times that the adjustment algorithm is executed in the aforementioned correction step for parallelization and the number of times that the adjustment algorithm is executed in the adjustment step.

A tension being applied to the mask 50 at a point in time where the adjustment algorithm has been executed a predetermined number of times may be recorded as adjusted tension.

The step S33 is followed by the step S31 of calculating the simple amplitude converted value ΔC of the mask 50 under adjusted tension. Then, the step S32 of determining whether the simple amplitude converted value ΔC is less than or equal to the first threshold TH1 is executed. As shown as a step S34 in FIG. 27, in a case where the simple amplitude converted value ΔC is greater than the first threshold TH1, the mask 50 may be judged as a defective product.

FIGS. 11A to 12B have shown an example in which the third end 503 of the intermediate portion 57 includes at least one concave portion 503a and at least one concave portion 503b with no tension being applied to the mask 50. A concave portion 503a and a convex portion 503b may appear at the third end 503 of a mask 50 corrected so that the first end portion 51 and the second end portion 52 become parallel to each other.

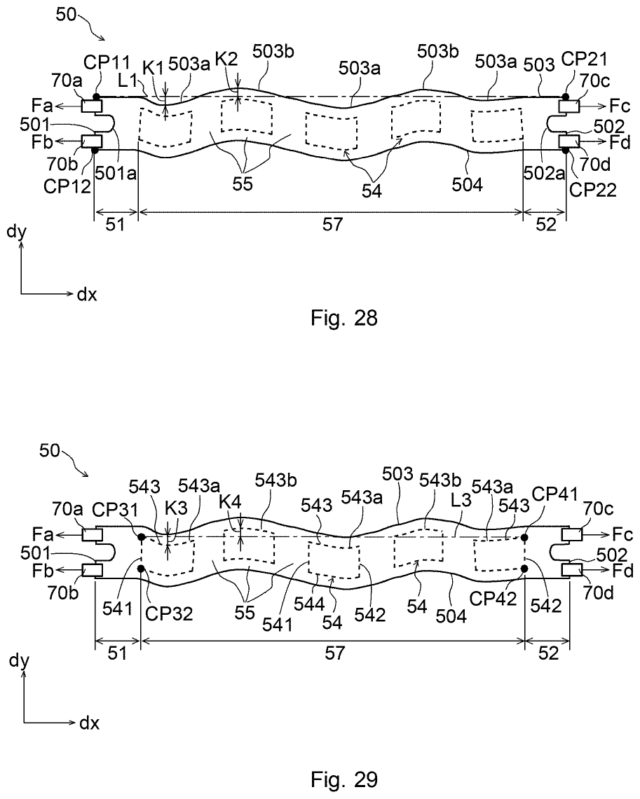

FIG. 28 is a plan view showing a mask 50 under parallelizing tension. In the mask 50 under parallelizing tension, the angle formed by the direction in which the first end 501 extends and the direction in which the second end 502 extends is less than or equal to 1 degree. In the example shown in FIG. 28, the parallelizing tension is defined as the minimum value of tension needed to make the angle less than or equal to 1 degree. In the example shown in FIG. 28, the direction in which the first end 501 extends is defined as the direction of a straight line connecting the eleventh cross point CP11 with a twelfth cross point CP12. The twelfth cross point CP12 is a point of intersection of the first end 501 and the fourth end 504. In the example shown in FIG. 28, the direction in which the second end 502 extends is defined as the direction of a straight line connecting the twenty-first cross point CP21 with a twenty-second cross point CP22. The twenty-second cross point CP22 is a point of intersection of the second end 502 and the fourth end 504.

In the mask 50 corrected so that the first end portion 51 and the second end portion 52 become parallel to each other, each of the concave portions 503a has a depth K1. The depth K1 is the maximum value of the distance between the concave portion 503a and the first straight line L1 in the y direction. The depth K1 may for example be greater than or equal to 0.2 μm, greater than or equal to 0.5 μm, greater than or equal to 1.0 μm, or greater than or equal to 2.0 μm. The depth K1 may for example be less than or equal to 4.0 μm, less than or equal to 7.0 μm, less than or equal to 10.0 μm, or less than or equal to 20.0 μm. The depth K1 may fall within a range defined by a first group consisting of 0.2 μm, 0.5 μm, 1.0 μm, and 2.0 μm and/or a second group consisting of 4.0 μm, 7.0 μm, 10.0 μm, and 20.0 μm. The depth K1 may fall within a range defined by a combination of any one of the values included in the aforementioned first group and any one of the values included In the aforementioned second group. The depth K1 may fall within a range defined by a combination of any two of the values included in the aforementioned first group. The depth K1 may fall within a range defined by a combination of any two of the values included in the aforementioned second group. The depth K1 may for example be greater than or equal to 0.2 μm and less than or equal to 20.0 μm, greater than or equal to 0.2 μm and less than or equal to 10.0 μm, greater than or equal to 0.2 μm and less than or equal to 7.0 μm, greater than or equal to 0.2 μm and less than or equal to 4.0 μm, greater than or equal to 0.2 μm and less than or equal to 2.0 μm, greater than or equal to 0.2 μm and less than or equal to 1.0 μm, greater than or equal to 0.2 μm and less than or equal to 0.5 μm, greater than or equal to 0.5 μm and less than or equal to 20.0 μm, greater than or equal to 0.5 μm and less than or equal to 10.0 μm, greater than or equal to 0.5 μm and less than or equal to 7.0 μm, greater than or equal to 0.5 μm and less than or equal to 4.0 μm, greater than or equal to 0.5 μm and less than or equal to 2.0 μm, greater than or equal to 0.5 μm and less than or equal to 1.0 μm, greater than or equal to 1.0 μm and less than or equal to 20.0 μm, greater than or equal to 1.0 μm and less than or equal to 10.0 μm, greater than or equal to 1.0 μm and less than or equal to 7.0 μm, greater than or equal to 1.0 μm and less than or equal to 4.0 μm, greater than or equal to 1.0 μm and less than or equal to 2.0 μm, greater than or equal to 2.0 μm and less than or equal to 20.0 μm, greater than or equal to 2.0 μm and less than or equal to 10.0 μm, greater than or equal to 2.0 μm and less than or equal to 7.0 μm, greater than or equal to 2.0 μm and less than or equal to 4.0 μm, greater than or equal to 4.0 μm and less than or equal to 20.0 μm, greater than or equal to 4.0 μm and less than or equal to 10.0 μm, greater than or equal to 4.0 μm and less than or equal to 7.0 μm, greater than or equal to 7.0 μm and less than or equal to 20.0 μm, greater than or equal to 7.0 μm and less than or equal to 10.0 μm, or greater than or equal to 10.0 μm and less than or equal to 20.0 μm.

In the mask 50 corrected so that the first end portion 51 and the second end portion 52 become parallel to each other, each of the convex portions 503b has a depth K2. The height K2 is the maximum value of the distance between the convex portion 503b and the first straight line L1 in the y direction. The range of numerical values of the height K2 may be identical to the aforementioned range of numerical values of the depth K1 of each of the concave portions 503a in the mask 50 corrected so that the first end portion 51 and the second end portion 52 become parallel to each other.

FIGS. 13A to 14 have shown an example in which the cell third contours 543 of the cells 54 include at least one inner portion 543a and at least one outer portion 543b with no tension being applied to the mask 50. The inner portion 543a and the outer portion 543b may appear on the cell third contours 543 of the cells 54 of a mask 50 corrected so that the first end portion 51 and the second end portion 52 become parallel to each other.

FIG. 29 is a plan view showing a mask 50 under parallelizing tension. In the mask 50 under parallelizing tension, the angle formed by the direction in which the first end 501 extends and the direction in which the second end 502 extends is less than or equal to 1 degree. In the example shown in FIG. 29, the parallelizing tension is defined as the minimum value of tension needed to make the angle less than or equal to 1 degree. In the example shown in FIG. 29, the direction in which the first end 501 extends Is defined as the direction of a straight line connecting the thirty-first cross point CP31 with a thirty-second cross point CP32. The thirty-second cross point CP32 is a point of intersection of the cell first contour 541 and the cell fourth contour 544 of a cell 54 that Is closest to the first end portion 51. In the example shown In FIG. 29, the direction in which the second end 502 extends is defined as the direction of a straight line connecting the forty-first cross point CP41 with a forty-second cross point CP42. The forty-second cross point CP42 is a point of intersection of the cell second contour 542 and the cell fourth contour 544 of a cell 54 that is closest to the second end portion 52.

In the mask 50 corrected so that the first end portion 51 and the second end portion 52 become parallel to each other, each of the inner portions 543a has a clearance K3. The clearance K3 is the maximum value of the distance between the inner portion 543a and the third straight line L3 in the y direction. The clearance K3 may for example be greater than or equal to 0.2 μm, greater than or equal to 0.5 μm, greater than or equal to 1.0 μm, or greater than or equal to 2.0 μm. The clearance K3 may for example be less than or equal to 4.0 μm, less than or equal to 7.0 μm, less than or equal to 10.0 μm, or less than or equal to 20.0 μm. The clearance K3 may fall within a range defined by a first group consisting of 0.2 μm, 0.5 μm, 1.0 μm, and 2.0 μm and/or a second group consisting of 4.0 μm, 7.0 μm, 10.0 μm, and 20.0 μm. The clearance K3 may fall within a range defined by a combination of any one of the values included in the aforementioned first group and any one of the values included in the aforementioned second group. The clearance K3 may fall within a range defined by a combination of any two of the values included in the aforementioned first group. The clearance K3 may fall within a range defined by a combination of any two of the values included in the aforementioned second group. The clearance K3 may for example be greater than or equal to 0.2 μm and less than or equal to 20.0 μm, greater than or equal to 0.2 μm and less than or equal to 10.0 μm, greater than or equal to 0.2 μm and less than or equal to 7.0 μm, greater than or equal to 0.2 μm and less than or equal to 4.0 μm, greater than or equal to 0.2 μm and less than or equal to 2.0 μm, greater than or equal to 0.2 μm and less than or equal to 1.0 μm, greater than or equal to 0.2 μm and less than or equal to 0.5 μm, greater than or equal to 0.5 μm and less than or equal to 20.0 μm, greater than or equal to 0.5 μm and less than or equal to 10.0 μm, greater than or equal to 0.5 μm and less than or equal to 7.0 μm, greater than or equal to 0.5 μm and less than or equal to 4.0 μm, greater than or equal to 0.5 μm and less than or equal to 2.0 μm, greater than or equal to 0.5 μm and less than or equal to 1.0 μm, greater than or equal to 1.0 μm and less than or equal to 20.0 μm, greater than or equal to 1.0 μm and less than or equal to 10.0 μm, greater than or equal to 1.0 μm and less than or equal to 7.0 μm, greater than or equal to 1.0 μm and less than or equal to 4.0 μm, greater than or equal to 1.0 μm and less than or equal to 2.0 μm, greater than or equal to 2.0 μm and less than or equal to 20.0 μm, greater than or equal to 2.0 μm and less than or equal to 10.0 μm, greater than or equal to 2.0 μm and less than or equal to 7.0 μm, greater than or equal to 2.0 μm and less than or equal to 4.0 μm, greater than or equal to 4.0 μm and less than or equal to 20.0 μm, greater than or equal to 4.0 μm and less than or equal to 10.0 μm, greater than or equal to 4.0 μm and less than or equal to 7.0 μm, greater than or equal to 7.0 μm and less than or equal to 20.0 μm, greater than or equal to 7.0 μm and less than or equal to 10.0 μm, or greater than or equal to 10.0 μm and less than or equal to 20.0 μm.

In the mask 50 corrected so that the first end portion 51 and the second end portion 52 become parallel to each other, each of the outer portions 543b has a clearance K4. The clearance K4 is the maximum value of the distance between the outer portion 543b and the third straight line L3 in the y direction. The range of numerical values of the clearance K4 may be identical to the aforementioned range of numerical values of the clearance K3 of each of the inner portions 543a in the mask 50 corrected so that the first end portion 51 and the second end portion 52 become parallel to each other.

### Examples

Next, the embodiment of the present disclosure is described In more concrete terms with reference to examples. However, the embodiment of the present disclosure is not limited to the following description of the examples, provided the embodiment of the present disclosure does not depart from the scope of the embodiment of the present disclosure.

The inspection method shown in FIG. 27 was used to inspect a large number of masks 50 to calculate ΔC and ΔS. The masks 50 were configured as follows and Inspected under the following conditions:
Lengths L of masks 50: 887 mm or greater and 889 mm or less
Widths W of masks 50: 67.8 mm or greater and 76.0 mm or less
Number of reference points arranged in x direction: 15
Initial values of parallelizing tensions Fa, Fb, Fc, and Fd in correction step: 3 N
Threshold THp of gaps Ga, Gb, Gc, and Gd: 0.5 μm
First threshold TH1: 1.11 μm
Second threshold TH2: 0.20 μm
Third threshold TH3: 1.8×ΔC+0.40 μm
Fourth threshold TH4: 1.8×ΔC+2.00 μm

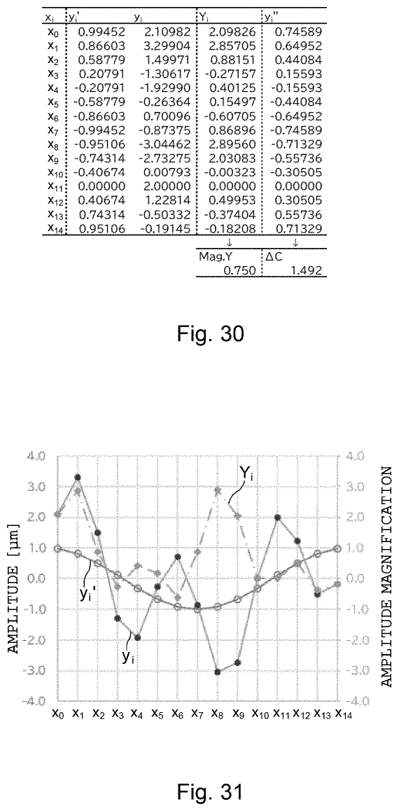

FIG. 30 is a graph showing examples of yᵢ, yᵢ′, Y₁, and yᵢ″. FIG. 31 is a graph showing examples of yᵢ, yᵢ′, and Yᵢ. Multiplying yᵢ by yᵢ′ gives Yᵢ. Mag.Y is calculated as the average of Yᵢ. Multiplying yᵢ′ by Mag.Y gives yᵢ″.

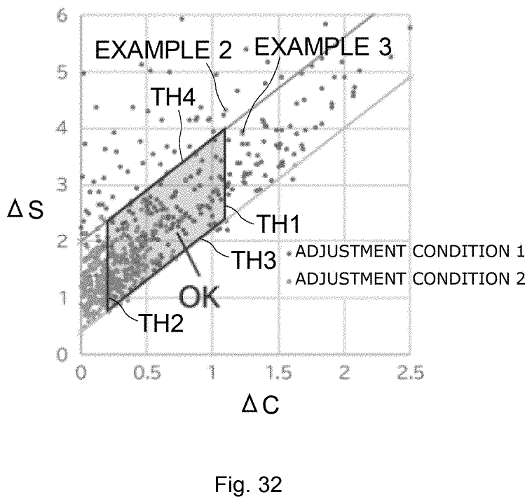

FIG. 32 is a graph showing a relationship between ΔC and ΔS. Dark markers indicate evaluation results obtained in cases where the adjustment algorithm was executed once. Light markers indicate evaluation results obtained In cases where the adjustment algorithm was executed six times. In the graph of FIG. 32, the first to fourth thresholds TH1 to TH4 are each represented by a straight line. A mask 50 with an evaluation result located In a region surrounded by the four straight lines corresponding to the first to fourth thresholds TH1 to TH4 is judged as an acceptable product.

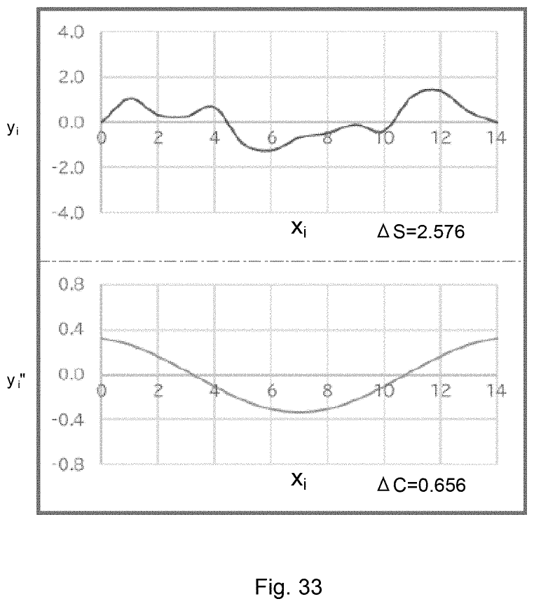

FIG. 33 is a graph showing yᵢ and yᵢ″ in a mask 50 of Example 1. In Example 1, the sum of the number of times that the adjustment algorithm was executed in the correction step for parallelization and the number of times that the adjustment algorithm was executed in the adjustment step is 6. The mask 50 of Example 1 is judged as an acceptable product.

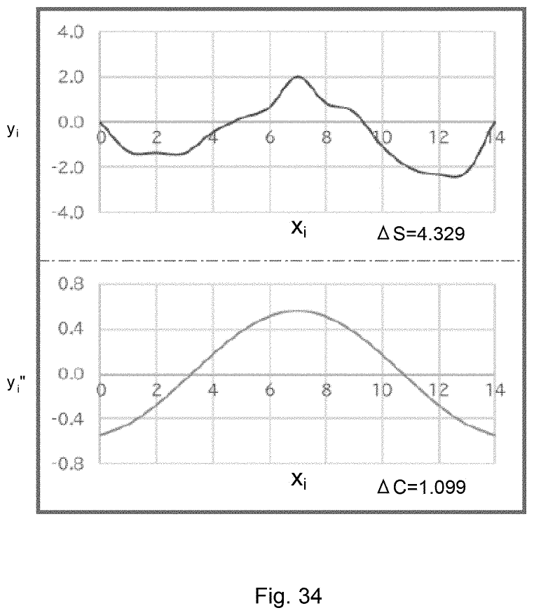

FIG. 34 is a graph showing yᵢ and yᵢ″ in a mask 50 of Example 2. In Example 2, the sum of the number of times that the adjustment algorithm was executed in the correction step for parallelization and the number of times that the adjustment algorithm was executed in the adjustment step is 6. As shown in FIG. 34, ΔS of the mask 50 of Example 2 is greater than the fourth threshold. For this reason, the mask 50 of Example 2 is judged as a defective product.

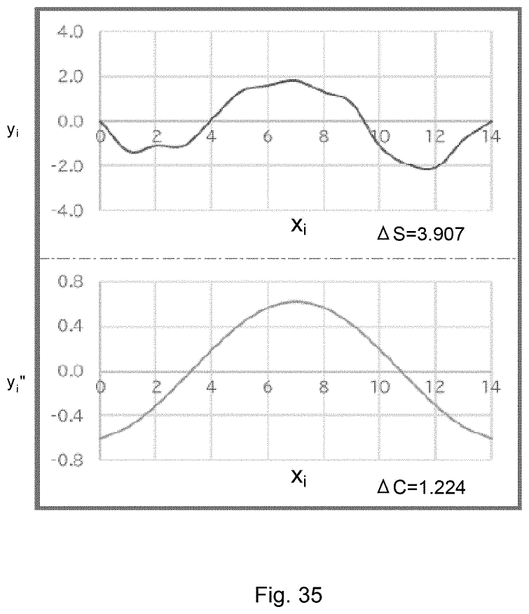

FIG. 35 is a graph showing yᵢ and yᵢ″ in a mask 50 of Example 3. In Example 3, the sum of the number of times that the adjustment algorithm was executed in the correction step for parallelization and the number of times that the adjustment algorithm was executed In the adjustment step is 6. As shown in FIG. 35, ΔC of the mask 50 of Example 3 is greater than the first threshold. For this reason, the mask 50 of Example 2 is judged as a defective product.

What is claimed is:

1. An method for inspecting a mask,
the mask including a first end portion and a second end portion that are opposite to each other in an x direction, a cell that is located between the first end portion and the second end portion and that includes a plurality of through holes, and n+1 (where n is a positive integer) reference points arranged in the x direction,
the method comprising:
a first calculation step of calculating y components y₀ to yₙ of coordinates of the reference points in a y direction orthogonal to the x direction;
an adjustment step of adjusting a tension so that a simple amplitude converted value ΔC calculated based on the y components y₀ to yₙ becomes less than or equal to a first threshold, the tension being applied to the mask; and
a second evaluation step of evaluating linearity of the mask with reference to amplitude ΔS calculated based on y components of coordinates of the reference points of the mask under the tension adjusted in the adjustment step.

2. The method according to claim 1, wherein
the first calculation step includes
a correction step of correcting the mask so that the first end portion and the second end portion become parallel to each other, and
a measuring step of measuring coordinates of the reference points of the mask thus corrected.

3. The method according to claim 1, wherein the adjustment step includes calculating amplitude magnifications Y₀ to Yₙ by multiplying the y components y₀ to yₙ by y components y′₀ to y′ₙ of a cosine function y′ that simulates a cosine wave, calculating an average amplitude magnification Mag.Y that is an average of the amplitude magnifications Y₀ to Yₙ, calculating simple amplitude converted components y″₀ to y″ₙ by multiplying the average amplitude magnification Mag.Y by the y components y′₀ to y′ₙ, and calculating the simple amplitude converted value ΔC as a difference between maximum and minimum values of the simple amplitude converted components y″₀ to y″ₙ.

4. The method according to claim 1, wherein the second evaluation step includes judging the mask as an acceptable product in a case where a difference ΔS between maximum and minimum values of the y components y₀ to y₀ is greater than or equal to a third threshold and less than or equal to a fourth threshold.

5. The method according to claim 4, wherein
the third threshold is 1.8×ΔC+0.40 μm, and
the fourth threshold is 1.8×ΔC+2.00 μm.

6. The method according to claim 1, wherein the first threshold is 1.11 μm.

7. The method according to claim 1, further comprising a first evaluation step of exempting the mask from evaluation in a case where the simple amplitude converted value ΔC is less than a second threshold.

8. The method according to claim 7, wherein the second threshold is 0.20 μm.

9. The method according to claim 7, wherein the second evaluation step is executed in a case where the simple amplitude converted value ΔC is greater than or equal to the second threshold and less than or equal to the first threshold.

10. A method for manufacturing a mask, comprising the steps of:
preparing a metal plate;
forming a plurality of through holes in the metal plate;
obtaining the mask by partially cutting out the metal plate with the through holes formed in the metal plate; and
inspecting the mask using the method according to claim 1.

11. An apparatus for inspecting a mask,
the mask including a first end portion and a second end portion that are opposite to each other in an x direction, a cell that is located between the first end portion and the second end portion and that includes a plurality of through holes, and n+1 (where n is a positive integer) reference points arranged in the x direction,
the apparatus comprising:
a first calculation device that calculates y components y₀ to yₙ of coordinates of the reference points in a y direction orthogonal to the x direction;
an adjustment device that adjusts a tension so that a simple amplitude converted value ΔC calculated based on the y components y₀ to yₙ becomes less than or equal to a first threshold, the tension being applied to the mask; and
a second evaluation device that evaluates linearity of the mask with reference to amplitude ΔS calculated based on y components of coordinates of the reference points of the mask under the tension adjusted by the adjustment device.

12. The apparatus according to claim 11, wherein
the first calculation device includes
a correction device that corrects the mask so that the first end portion and the second end portion become parallel to each other, and
a measuring device that measures coordinates of the reference points of the mask thus corrected.

13. The apparatus according to claim 11, wherein the adjustment device calculates amplitude magnifications Y₀ to Yₙ by multiplying the y components y₀ to yₙ by y components y′₀ to y′ₙ of a cosine function y′ that simulates a cosine wave, calculates an average amplitude magnification Mag.Y that is an average of the amplitude magnifications Y₀ to Yₙ, calculates simple amplitude converted components y″₀ to y″ₙ by multiplying the average amplitude magnification Mag.Y by the y components y′₀ to y′ₙ, and calculates the simple amplitude converted value ΔC as a difference between maximum and minimum values of the simple amplitude converted components y″₀ to y″ₙ.

14. A computer-readable non-transient storage medium comprising a program for causing a computer to function as the adjustment device and the second evaluation device of the apparatus according to claim 11.

15. A mask comprising:
a first end portion and a second end portion that are opposite to each other in an x direction;
an intermediate portion including one or more cells that are located between the first end portion and the second end portion and each of which includes a plurality of through holes; and
n+1 (where n is a positive integer) arranged in the x direction,
wherein
the mask has an adjusted tension,
the adjusted tension is a tension at which a simple amplitude converted value ΔC calculated based on y components y₀ to yₙ of coordinates of the reference points in a y direction orthogonal to the x direction can be made less than or equal to a first threshold value,
the first threshold is 1.11 μm,
the simple amplitude converted value ΔC is a difference between maximum and minimum values of simple amplitude converted components y″₀ to y″ₙ,
the simple amplitude converted components y″₀ to y″ₙ are calculated by multiplying an average amplitude magnification Mag.Y by y components y′₀ to y′ₙ of a cosine function that simulates a cosine wave,
the average amplitude magnification Mag.Y is an average of amplitude magnifications Y₀ to Yₙ calculated by multiplying the y components y₀ to yₙ by the y components y′₀ to y′ₙ,
when under the adjusted tension, the mask has amplitude ΔS that is greater than or equal to a third threshold and less than or equal to a fourth threshold,
the amplitude ΔS is a difference between maximum and minimum values of y components y₀ to yₙ of coordinates of the reference points of the mask under the adjusted tension,
the third threshold is 1.8×ΔC+0.40 μm, and
the fourth threshold is 1.8×ΔC+2.00 μm.

16. The mask according to claim 15, wherein the y components y₀ to yₙ are calculated by measuring coordinates of the reference points with the mask corrected so that the first end portion and the second end portion become parallel to each other.

17. The mask according to claim 15, wherein the simple amplitude converted value ΔC is greater than or equal to 0.20 μm.

18. The mask according to claim 15, further comprising:
a first end and a second end that are ends of the mask in the x direction; and
a third end and a fourth end that are ends of the mask in the y direction,
wherein
each of the one or more cells includes a cell third contour extending along the third end, a cell fourth end extending along the fourth end, a cell first contour extending from a cell first end of the cell third contour to a cell first end of the cell fourth contour, and a cell second contour extending from a cell second end of the cell third contour to a cell second end of the cell fourth end,
the cell third contours of the one or more cells include at least one inner portion and at least one outer portion with the mask corrected so that the first end portion and the second end portion become parallel to each other,
the inner portion is located further inward than a third straight line,
the outer portion is located further outward than the third straight line,
the third straight line is an imaginary line connecting a thirty-first cross point with a forty-first cross point,
the thirty-first cross point is a point of intersection of the cell first contour and the cell third contour of one of the cells that is closest to the first end portion, and
the forty-first cross point is a point of intersection of the cell second contour and the cell third contour of one of the cells that is closest to the second end portion.

19. The mask according to claim 15, further comprising:
a first end and a second end that are ends of the mask in the x direction; and
a third end and a fourth end that are ends of the mask in the y direction,
wherein
each of the one or more cells includes a cell third contour extending along the third end, a cell fourth end extending along the fourth end, a cell first contour extending from a cell first end of the cell third contour to a cell first end of the cell fourth contour, and a cell second contour extending from a cell second end of the cell third contour to a cell second end of the cell fourth end,
the cell third contours of the one or more cells include at least one inner portion and at least one outer portion with no tension being applied to the mask,
the inner portion is located further inward than a third straight line,
the outer portion is located further outward than the third straight line,
the third straight line is an imaginary line connecting a thirty-first cross point with a forty-first cross point,
the thirty-first cross point is a point of intersection of the cell first contour and the cell third contour of one of the cells that is closest to the first end portion, and
the forty-first cross point is a point of intersection of the cell second contour and the cell third contour of one of the cells that is closest to the second end portion.
